(19) United States
(12) Patent Application Publication
(10) Pub. No.: US 2010/0086878 A1
(43) Pub. Date: Apr. 8, 2010

(54) PATTERNING PROCESS

(75) Inventors: Jun Hatakeyama, Joetsu-shi (JP); Masashi Iio, Joetsu-shi (JP); Takeru Watanabe, Joetsu-shi (JP); Takeshi Kinsho, Joetsu-shi (JP); Toshinobu Ishihara, Joetsu-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: SHIN-ETSU CHEMICAL CO., LTD., Tokyo (JP)

(21) Appl. No.: 12/575,097

(22) Filed: Oct. 7, 2009

(30) Foreign Application Priority Data
Oct. 7, 2008 (JP) 2008-260512

(51) Int. Cl. G03F 7/20

(52) U.S. Cl. 430/324

(57) ABSTRACT

A pattern is formed by applying a first positive resist material onto a substrate, heat treating, exposing to high-energy radiation, heat treating, then developing with a developer to form a first resist pattern; applying a protective coating solution comprising a hydrolyzable silicon compound having an amino group onto the first resist pattern and the substrate, heating to form a protective coating; and applying a second positive resist material thereon, heat treating, exposing to high-energy radiation, heat treating, and then developing with a developer to form a second resist pattern. By forming the second pattern in a space portion of the first pattern, this double patterning reduces the pattern pitch to one half.

### CROSS-REFERENCE TO RELATED APPLICATION

This non-provisional application claims priority under 35 U.S.C. §119(a) on Patent Application No. 2008-260512 filed in Japan on Oct. 7, 2008, the entire contents of which are hereby incorporated by reference.

### TECHNICAL FIELD

This invention relates to a double patterning process involving the steps of forming a first positive pattern from a first photoresist film through exposure and development, applying a solution containing a silane having an amino group and a hydrolysis reactive group on the pattern surface, treating for rendering the first resist pattern insoluble in resist solvent and developer, applying a second photoresist film thereon, and forming a second positive pattern in the selected portion of the first resist pattern, typically in spaces between first resist pattern features.

### BACKGROUND ART

In the recent drive for higher integration and operating speeds in LSI devices, the pattern rule is made drastically finer. The photolithography which is currently on widespread use in the art is approaching the essential limit of resolution determined by the wavelength of a light source. As the light source used in the lithography for resist pattern formation, g-line (436 nm) or i-line (365 nm) from a mercury lamp was widely used in 1980's. Reducing the wavelength of exposure light was believed effective as the means for further reducing the feature size. For the mass production process of 64 MB dynamic random access memories (DRAM, processing feature size 0.25 μm or less) in 1990's and later ones, the exposure light source of i-line (365 nm) was replaced by a KrF excimer laser having a shorter wavelength of 248 nm. However, for the fabrication of DRAM with a degree of integration of 256 MB and 1 GB or more requiring a finer patterning technology (processing feature size 0.2 μm or less), a shorter wavelength light source was required. Over a decade, photolithography using ArF excimer laser light (193 nm) has been under active investigation. It was expected at the initial that the ArF lithography would be applied to the fabrication of 180-nm node devices. However, the KrF excimer lithography survived to the mass-scale fabrication of 130-nm node devices. So, the full application of ArF lithography started from the 90-nm node. The ArF lithography combined with a lens having an increased numerical aperture (NA) of 0.9 is considered to comply with 65-nm node devices. For the next 45-nm node devices which required an advancement to reduce the wavelength of exposure light, the F₂ lithography of 157 nm wavelength became a candidate. However, for the reasons that the projection lens uses a large amount of expensive CaF₂ single crystal, the scanner thus becomes expensive, hard pellicles are introduced due to the extremely low durability of soft pellicles, the optical system must be accordingly altered, and the etch resistance of resist is low; the postponement of F₂ lithography and the early introduction of ArF immersion lithography were advocated (see Proc. SPIE Vol. 4690 xxix, 2002).

In the ArF immersion lithography, the space between the projection lens and the wafer is filled with water. Since water has a refractive index of 1.44 at 193 nm, pattern formation is possible even using a lens having a numerical aperture (NA) of 1.0 or greater. Theoretically, it is possible to increase the NA to nearly 1.44. It was initially recognized that the resolution could be degraded and the focus be shifted by a variation of water's refractive index with a temperature change. The problem of refractive index variation could be solved by controlling the water temperature within a tolerance of 1/100° C. while it was recognized that the impact of heat from the resist film upon light exposure drew little concern. There was a likelihood that micro-bubbles in water could be transferred to the pattern. It was found that the risk of bubble generation is obviated by thorough deaeration of water and the risk of bubble generation from the resist film upon light exposure is substantially nil. At the initial phase in 1980's of the immersion lithography, a method of immersing an overall stage in water was proposed. Later proposed was a partial-fill method of using a water feed/drain nozzle for introducing water only between the projection lens and the wafer so as to comply with the operation of a high-speed scanner. In principle, the immersion technique using water enabled lens design to a NA of 1 or greater. In optical systems based on traditional refractive index materials, this leads to giant lenses, which would deform by their own weight. For the design of more compact lenses, a catadioptric system was proposed, accelerating the lens design to a NA of 1.0 or greater. A combination of a lens having NA of 1.2 or greater with strong resolution enhancement technology suggests a way to the 45-nm node (see Proc. SPIE, Vol. 5040, p 724, 2003). Efforts have also been made to develop lenses of NA 1.35.

One candidate for the 32-nm node lithography is lithography using extreme ultraviolet (EUV) radiation with wavelength 13.5 nm. The EUV lithography has many accumulative problems to be overcome, including increased laser output, increased sensitivity, increased resolution and minimized line width roughness (LWR) of resist film, defect-free MoSi laminate mask, reduced aberration of reflection mirror, and the like.

The water immersion lithography using a NA 1.35 lens achieves an ultimate resolution of 40 to 38 nm at the maximum NA, but cannot reach 32 nm. Efforts have been made to develop higher refractive index materials in order to further increase NA. It is the minimum refractive index among projection lens, liquid, and resist film that determines the NA limit of lenses. In the case of water immersion, the refractive index of water is the lowest in comparison with the projection lens (refractive index 1.5 for synthetic quartz) and the resist film (refractive index 1.7 for prior art methacrylate-based film). Thus the NA of projection lens is determined by the refractive index of water. Recent efforts succeeded in developing a highly transparent liquid having a refractive index of 1.65. In this situation, the refractive index of projection lens made of synthetic quartz is the lowest, suggesting a need to develop a projection lens material with a higher refractive index. LuAG (lutetium aluminum garnet Lu₃Al₅O₁₂) having a refractive index of at least 2 is the most promising material, but has the problems of birefringence and noticeable absorption. Even if a projection lens material with a refractive index of 1.8 or greater is developed, the liquid with a refractive index of 1.65 limits the NA to 1.55 at most, failing in resolution of 32 nm. For resolution of 32 nm, a liquid with a refractive index of 1.8 or greater is necessary. Such a liquid material has not been discovered because a tradeoff between absorption and refractive index is recognized in the art. In the case of alkane compounds, bridged cyclic compounds are preferred to linear ones in order to increase the refractive index, but the cyclic compounds undesirably have too high a viscosity to follow high-speed scanning on the exposure tool stage. If a liquid with a refractive index of 1.8 is developed, then the component having the lowest refractive index is the resist film, suggesting a need to increase the refractive index of a resist film to 1.8 or higher.

The process that now draws attention under the above-discussed circumstances is a double patterning process involving a first set of exposure and development to form a first pattern and a second set of exposure and development to form a pattern between features of the first pattern. See Proc. SPIE, Vol. 5992, 59921Q-1-16 (2005). A number of double patterning processes are proposed. One exemplary process involves a first set of exposure and development to form a photoresist pattern having lines and spaces at intervals of 1:3, processing the underlying layer of hard mask by dry etching, applying another layer of hard mask thereon, a second set of exposure and development of a photoresist film to form a line pattern in the spaces of the first exposure, and processing the hard mask by dry etching, thereby forming a line-and-space pattern at a half pitch of the first pattern. An alternative process involves a first set of exposure and development to form a photoresist pattern having spaces and lines at intervals of 1:3, processing the underlying layer of hard mask by dry etching, applying a photoresist layer thereon, a second set of exposure and development to form a second space pattern on the remaining hard mask portion, and processing the hard mask by dry etching. In either process, the hard mask is processed by two dry etchings.

While the former process requires two applications of hard mask, the latter process uses only one layer of hard mask, but requires to form a trench pattern which is difficult to resolve as compared with the line pattern. The latter process includes the use of a negative resist material in forming the trench pattern. This allows for use of high contrast light as in the formation of lines as a positive pattern. However, since the negative resist material has a lower dissolution contrast than the positive resist material, a comparison of the formation of lines from the positive resist material with the formation of a trench pattern of the same size from the negative resist material reveals that the resolution achieved with the negative resist material is lower. After a wide trench pattern is formed from the positive resist material by the latter process, there may be applied a thermal flow method of heating the substrate for shrinkage of the trench pattern, or a RELACS method of coating a water-soluble film on the trench pattern as developed and heating to induce crosslinking at the resist film surface for achieving shrinkage of the trench pattern. These have the drawbacks that the proximity bias is degraded and the process is further complicated, leading to reduced throughputs.

Both the former and latter processes require two etchings for substrate processing, leaving the issues of a reduced throughput and deformation and misregistration of the pattern by two etchings.

One method that proceeds with a single etching is by using a negative resist material in a first exposure and a positive resist material in a second exposure. Another method is by using a positive resist material in a first exposure and a negative resist material in a higher alcohol of 4 or more carbon atoms, in which the positive resist material is not dissolvable, in a second exposure. Since negative resist materials with low resolution are used, these methods entail degradation of resolution.

A method which dispenses with post-exposure bake (PEB) and development between first and second exposures is the simplest method. This method involves first exposure, replacement by a mask having a shifted pattern drawn, second exposure, PEB, development and dry etching. Since the throughput is substantially reduced by mask replacement on every exposure, the first exposure is carried out in a somewhat integrated manner before the second exposure is carried out. Then, depending on the holding time between the first exposure and the second exposure, a dimensional variation due to acid diffusion and a profile variation such as T-top profile formation occur. To suppress the T-top formation, application of a resist protective film is effective. Application of a resist protective film for immersion lithography enables a process involving two exposures, one PEB, development and dry etching. First exposure and second exposure may be consecutively carried out by two scanners arranged side by side. This gives rise to such problems as misregistration due to lens aberration between the two scanners and the doubled scanner cost.

If first exposure is followed by second exposure at a half-pitch shifted position, the optical energy of second exposure offsets the optical energy of first exposure so that the contrast becomes zero. If a contrast enhancement layer (CEL) is formed on the resist film, the incident light to the resist film becomes nonlinear so that the first and second exposures do not offset each other. Thus an image having a half pitch is formed. See Jpn. J. Appl. Phy. Vol. 33 (1994) p 6874-6877. It is expected that similar effects are produced by using an acid generator capable of two photon absorption to provide a nonlinear contrast.

The critical issue associated with double patterning is an overlay accuracy between first and second patterns. Since the magnitude of misregistration is reflected by a variation of line size, an attempt to form 32-nm lines at an accuracy of 10%, for example, requires an overlay accuracy within 3.2 nm. Since currently available scanners have an overlay accuracy of the order of 8 nm, a significant improvement in accuracy is necessary.

Now under investigation is the resist pattern freezing technology involving forming a first resist pattern on a substrate, taking any suitable means for insolubilizing the resist pattern with respect to the resist solvent and alkaline developer, applying a second resist thereon, and forming a second resist pattern in space portions of the first resist pattern. With this freezing technology, etching of the substrate is required only once, leading to improved throughputs and avoiding the problem of misregistration due to stress relaxation of the hard mask during etching.

With respect to the freezing technology, a number of reports have been published. Known are thermal insolubilization (Proc. SPIE Vol. 6923, p 69230G (2008)); coating of a cover film and thermal insolubilization (Proc. SPIE Vol. 6923, p 69230H (2008)); insolubilization by irradiation of light having an extremely short wavelength, for example, 172 nm wavelength (Proc. SPIE Vol. 6923, p 692321 (2008)); insolubilization by ion implantation (Proc. SPIE Vol. 6923, p 692322 (2008)); insolubilization through formation of thin-film oxide coating by CVD; insolubilization by light irradiation and special gas treatment (Proc. SPIE Vol. 6923, p 69233C1 (2008)); insolubilization of a resist pattern by treatment of resist pattern surface with a metal alkoxide or metal halide (e.g., titanium, zirconium or aluminum) or an isocyanate-containing silane compound (JP-A 2008-33174); and insolubilization of a resist pattern by coating its surface with water-soluble resin (JP-A 2008-83537). These insolubilization treatments give rise to problems of pattern deformation, film thinning, and size narrowing or widening, which must be overcome.

As compared with the line pattern, the hole pattern is difficult to reduce its size. If an attempt is made to form fine holes according to the prior art method by combining a positive resist film with a hole pattern mask and effecting under-exposure, the exposure margin is extremely narrowed. It is then proposed to form holes of larger size and shrink the developed holes by thermal flow, RELACS or other techniques. However, there is a substantial difference between the pattern size as developed and the pattern size as shrunk, giving rise to the problem that a greater shrinkage leads to a lower control accuracy. JP 4045430 discloses a RELACS technique using a water-soluble silicone polymer. This patent describes a hole shrinkage example using a silicone bilayer resist comprising an amino group-containing polysilsesquioxane and a conventional hydrocarbon-based resist. It is also proposed in Proc. SPIE Vol. 5377 p 255 (2004) to form a positive resist film, form a X-direction line pattern therein by dipolar illumination, curing the resist pattern, applying a resist material thereon again, and exposing the resist film to a Y-direction line pattern by dipolar illumination, whereby interstices between grid-like line patterns define a hole pattern. Insolubilization of the first resist pattern is necessary.

An insolubilizing technique of applying a curable film material on a resist film and curing a surface portion of the resist film may be contemplated. A problem arises that the curable film material deposits on the resist surface so that the size is thickened. If the thickness of the cured film on the resist surface is reduced, it is not resistant to penetration of a resist solvent during application of a second resist material or penetration of an alkaline developer during second development, and as a result, the first resist pattern can be extinguished or reduced in size. It is desired to form a fully robust crosslinkable film on the resist surface.

A study is made on surface modification by aminosilane treatment. The aminosilane treatment makes the surface hydrophilic. JP-A H05-258612 discloses aminosilane treatment of a polyethylene-covered electric cable to render the cable hydrophilic for preventing its electric insulation from being deteriorated in a humid atmosphere. JP-A H06-152110 discloses aminosilane treatment of a metal circuit to render the metal surface hydrophilic for improving the adhesion thereof to the overlying insulating resin. JP-A 2006-65035 discloses to cover a resist pattern with a water-soluble amino-containing titanium compound for improving the etch resistance of the resist pattern, indicating adsorption of the water-soluble amino-containing titanium compound on the resist pattern surface.

### Citation List

Patent Document 1: JP-A 2008-33174
Patent Document 2: JP-A 2008-83537
Patent Document 3: JP 4045430
Patent Document 4: JP-A H05-258612
Patent Document 5: JP-A H06-152110
Patent Document 6: JP-A 2006-65035
Patent Document 7: U.S. Pat. No. 7,537,880 (JP-A 2008-111103)
Non-patent Document 1: Proc. SPIE Vol. 4690 xxix (2002)
Non-patent Document 2: Proc. SPIE Vol. 5040 p 724 (2003)
Non-patent Document 3: Proc. SPIE Vol. 5992 59921Q-1-16 (2005)
Non-patent Document 4: Jpn. J. Appl. Phy. Vol. 33 (1994) p 6874-6877
Non-patent Document 5: Proc. SPIE Vol. 6923 p 69230G (2008)
Non-patent Document 6: Proc. SPIE Vol. 6923 p 69230H (2008)
Non-patent Document 7: Proc. SPIE Vol. 6923 p 692321 (2008)
Non-patent Document 8: Proc. SPIE Vol. 6923 p 692322 (2008)
Non-patent Document 9: Proc. SPIE Vol. 6923 p 69233C1 (2008)
Non-patent Document 10: Proc. SPIE Vol. 5377 p 255 (2004)

### SUMMARY OF INVENTION

In connection with the double patterning process involving forming a first positive resist pattern through exposure and development, insolubilizing the first positive resist pattern, applying a second positive resist material thereon, and forming a second positive resist pattern in a space portion of the first positive resist pattern, it would be desirable to have a pattern surface coating material capable of efficiently insolubilizing the first positive resist pattern for minimizing the variation of the first pattern size.

Therefore, an object of the invention is to provide a pattern forming process capable of efficiently insolubilizing the first positive resist pattern, thus achieving effective double patterning.

It has been found that better results are obtained when a pattern forming process involving forming a first resist pattern, then coating and processing a second resist film to form a second resist pattern in a space portion of the first resist pattern is tailored as follows.

[1] A patterning process comprising the steps of:

applying a first positive resist material onto a substrate, heat treating to form a first resist film, exposing it to high-energy radiation, heat treating the exposed first resist film, then developing it with a developer to form a first resist pattern,

applying a protective coating solution onto the first resist pattern and the substrate, said protective coating solution comprising a silicon compound having at least one amino group and a hydrolysis reactive group, heating the protective coating solution to form a protective coating covering the surface of the first resist pattern,

applying a second positive resist material on the protective coating, heat treating to form a second resist film, exposing it to high-energy radiation, heat treating the exposed second resist film, and then developing it with a developer.

[2] A patterning process comprising the steps of:

applying a first positive resist material onto a substrate, heat treating to form a first resist film, exposing it to high-energy radiation, heat treating the exposed first resist film, then developing it with a developer to form a first resist pattern,

applying a protective coating solution onto the first resist pattern and the substrate, said protective coating solution comprising a silicon compound having at least one amino group and a hydrolysis reactive group, heating the protective coating solution to form a protective coating covering the surface of the first resist pattern, stripping an extra portion of the protective coating using an alkaline developer, solvent, water or a mixture thereof,

applying a second positive resist material on the protective coating and the substrate, heat treating to form a second resist film, exposing it to high-energy radiation, heat treating the exposed second resist film, and then developing it with a developer.

[3] A patterning process comprising the steps of:

applying a first positive resist material onto a substrate, heat treating to form a first resist film, exposing it to high-energy radiation, heat treating the exposed first resist film, then developing it with a developer to form a first resist pattern,

applying a protective coating solution onto the first resist pattern and the substrate, said protective coating solution comprising a silicon compound having at least one amino group and a hydrolysis reactive group,

applying heat for crosslinking and curing the surface of the first resist pattern adjacent to the protective coating, stripping a non-crosslinked portion of the protective coating using an alkaline developer, solvent, water or a mixture thereof,

applying further heat for insolubilizing the surface of the first resist film,

applying a second positive resist material on the protective coating and the substrate, heat treating to form a second resist film, exposing it to high-energy radiation, heat treating the exposed second resist film, and then developing it with a developer.

[4] The patterning process of any one of [1] to [3] wherein the hydrolysis reactive group is an alkoxy group.
[5] The patterning process of any one of [1] to [3] wherein the silicon compound having at least one amino group and a hydrolysis reactive group is a silane compound having the general formula (1) or (2) or a (partial) hydrolytic condensate thereof.

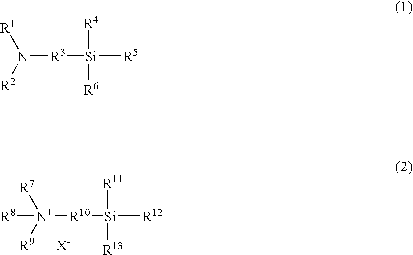

Herein R¹, R², R⁷, R⁸ and R⁹ are each independently hydrogen, a straight, branched or cyclic C₁-C₁₀ alkyl group which may have an amino, ether (—O—), ester (—COO—) or hydroxyl group, or a C₆-C₁₀ aryl, C₂-C₁₂ alkenyl or C₇-C₁₂ aralkyl group which may have an amino group, or R¹ and R², R⁷ and R⁸, R⁸ and R⁹, or R⁷ and R⁹ may bond together to form a ring with the nitrogen atom to which they are attached, R³ and R¹⁰ are each independently a straight, branched or cyclic C₁-C₁₂ alkylene group which may have an ether (—O—), ester (—COO—), thioether (—S—), phenylene or hydroxyl group, R⁴ to R⁶ and R¹¹ to R¹³ are each independently hydrogen, a C₁-C₆ alkyl, C₆-C₁₀ aryl, C₂-C₁₂ alkenyl, C₁-C₆ alkoxy, C₆-C₁₀ aryloxy, C₂-C₁₂ alkenyloxy, C₇-C₁₂ aralkyloxy or hydroxyl group, at least one of R⁴ to R⁶ and R¹¹ to R¹³ being alkoxy or hydroxyl, and X⁻ is an anion.
[6] The patterning process of any one of [1] to [3] wherein the silicon compound having at least one amino group and a hydrolysis reactive group is a silane compound having the general formula (3) or (4) or a (partial) hydrolytic condensate thereof.

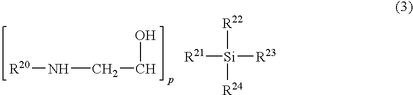

Herein R²⁰ is hydrogen, or a straight, branched or cyclic C₁-C₂₀ alkyl, C₆-C₁₀ aryl or C₂-C₁₂ alkenyl group which may have a hydroxyl, ether, ester or amino group, p is 1 or 2, when p is 1, R²¹ is a straight, branched or cyclic C₁-C₂₀ alkylene group which may have an ether, ester or phenylene group, when p is 2, R²¹ is the alkylene group with one hydrogen atom being eliminated, R²² to R²⁴ are each independently hydrogen, or a C₁-C₆ alkyl, C₆-C₁₀ aryl, C₂-C₁₂ alkenyl, C₁-C₆ alkoxy, C₆-C₁₀ aryloxy, C₂-C₁₂ alkenyloxy, C₇-C₁₂ aralkyloxy or hydroxyl group, at least one of R²² to R²⁴ being alkoxy or hydroxyl.

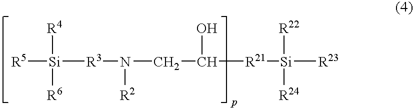

Herein R² is hydrogen, a straight, branched or cyclic C₁-C₁₀ alkyl group which may have an amino, ether (—O—), ester (—COO—) or hydroxyl group, or a C₆-C₁₀ aryl, C₂-C₁₂ alkenyl or C₇-C₁₂ aralkyl group which may have an amino group, R³ is a straight, branched or cyclic C₁-C₁₂ alkylene group which may have an ether (—O—), ester (—COO—), thioether (—S—), phenylene or hydroxyl group, R⁴ to R⁶ are each independently hydrogen, a C₁-C₆ alkyl, C₆-C₁₀ aryl, C₂-C₁₂ alkenyl, C₁-C₆ alkoxy, C₆-C₁₀ aryloxy, C₂-C₁₂ alkenyloxy, C₇-C₁₂ aralkyloxy or hydroxyl group, at least one of R⁴ to R⁶ being alkoxy or hydroxyl, and R²¹ to R²⁴ and p are as defined above.
[7] The patterning process of any one of [1] to [6] wherein the protective coating solution further comprises a silane compound having the general formula (5) and/or a water-soluble resin.

R³¹ₘ₁R³²ₘ₂R³³ₘ₃Si(OR)₍₄₋ₘ₁₋ₘ₂₋ₘ₃₎ (5)

Herein R is C₁-C₃ alkyl, R³¹, R³² and R³³ are each independently hydrogen or C₁-C₃₀ monovalent organic group, m1, m2 and m3 are each equal to 0 or 1, and m1+m2+m3 is 0 to 3.
[8] The patterning process of any one of [1] to [7] wherein the protective coating solution further comprises a monohydric alcohol of 3 to 8 carbon atoms and/or water.
[9] The patterning process of any one of [1] to [8] wherein the exposure steps to form the first and second resist patterns are carried out by immersion lithography including using an ArF excimer laser of 193 nm wavelength and holding a liquid having a refractive index of at least 1.4 between a lens and the substrate.

[10] The patterning process of [9] wherein the liquid having a refractive index of at least 1.4 is water.

[11] The patterning process of any one of [1] to [10] wherein the second pattern is formed in a space portion of the first pattern whereby the distance between pattern features is reduced.

[12] The patterning process of any one of [1] to [10] wherein the second pattern is formed so as to intersect the first pattern.
[13] The patterning process of any one of [1] to [10] wherein in a space portion where features of the first pattern are not formed, the second pattern is formed in a direction different from the first pattern.
[14] The patterning process of any one of [1] to [13], further comprising the step of applying a silicon-containing film as a bottom layer film beneath the resist.
[15] The patterning process of any one of [1] to [14], further comprising the steps of forming a carbon film having a carbon content of at least 75% by weight on a processable substrate, and applying a silicon-containing intermediate film thereon, prior to the formation of the resist film.

### ADVANTAGEOUS EFFECTS OF INVENTION

According to the invention, a first positive resist material is applied, a first resist pattern is formed therein through exposure and development, a silicon compound having an amino group and a hydrolysis reactive group is coated, and heat is applied to cure the pattern surface so as to be insoluble in alkaline developer and resist solution. A second resist material is applied thereon, a second resist pattern is formed therein through exposure and development, for example, so that the second pattern is located in a space portion of the first pattern. This double patterning reduces the pitch between patterns to one half. The substrate can be processed by a single dry etching.

### BRIEF DESCRIPTION OF THE DRAWINGS

FIG. 1 is a cross-sectional view of an exemplary prior art double patterning process. FIG. 1-A shows a laminate of substrate, processable substrate, hard mask and resist film, FIG. 1-B shows the resist film being exposed and developed, FIG. 1-C shows the hard mask being etched, FIG. 1-D shows a second resist film being formed, exposed and developed, and FIG. 1-E shows the processable substrate being etched.

FIG. 2 is a cross-sectional view of another exemplary prior art double patterning process. FIG. 2-A shows a laminate of substrate, processable substrate, 1st and 2nd hard masks and resist film, FIG. 2-B shows the resist film being exposed and developed, FIG. 2-C shows the 2nd hard mask being etched, FIG. 2-D shows, after removal of the first resist film, a second resist film being formed, exposed and developed, FIG. 2-E shows the 1st hard mask being etched, and FIG. 2-F shows the processable substrate being etched.

FIG. 3 is a cross-sectional view of a further exemplary prior art double patterning process. FIG. 3-A shows a laminate of substrate, processable substrate, hard mask and resist film, FIG. 3-B shows the resist film being exposed and developed, FIG. 3-C shows the hard mask being etched, FIG. 3-D shows, after removal of the first resist film, a second resist film being formed, exposed and developed, FIG. 3-E shows the hard mask being etched, and FIG. 3-F shows the processable substrate being etched.

FIG. 4 is a cross-sectional view of a patterning process according one embodiment of the invention. FIG. 4-A shows a laminate of substrate, processable substrate, hard mask and first resist film, FIG. 4-B shows the first resist film being exposed and developed, FIG. 4-C shows a protective coating material being coated and crosslinked on the first resist pattern, FIG. 4-D shows a second positive resist material being coated, FIG. 4-E shows a second resist pattern being formed, FIG. 4-F shows extra portions of the crosslinked film and hardmask being etched away, and FIG. 4-G shows the processable substrate being etched.

FIG. 5 is a cross-sectional view of a patterning process according another embodiment of the invention. FIG. 5-A shows a laminate of substrate, processable substrate, hard mask and first resist film, FIG. 5-B shows the first resist film being exposed and developed, FIG. 5-C shows a protective coating material being coated and crosslinked on the first resist pattern, FIG. 5-D shows an extra portion of the protective film being removed, FIG. 5-E shows a second positive resist material being coated, FIG. 5-F shows a second resist pattern being formed, FIG. 5-G shows the extra crosslinked film and hardmask being etched away, and FIG. 5-H shows the processable substrate being etched.

FIG. 6 is a top-down view of a double patterning process according an embodiment of the invention. FIG. 6-A shows a first pattern being formed, and FIG. 6-B shows a second pattern being formed, after formation of the first pattern, so as to intersect the first pattern.

FIG. 7 is a top-down view of a double patterning process according another embodiment of the invention. FIG. 7-A shows a first pattern being formed, and FIG. 7-B shows a second pattern being formed after formation of the first pattern and spaced from the first pattern.

### DESCRIPTION OF EMBODIMENTS

The singular forms “a,” an and the include plural referents unless the context clearly dictates otherwise.

As used herein, the terminology “(Cₓ-C_{y})”, as applied to a particular unit, such as, for example, a chemical compound or a chemical substituent group, means having a carbon atom content of from “x” carbon atoms to “y” carbon atoms per such unit.

In connection with the double patterning lithography involving double exposures and developments to form a half-pitch pattern, the inventors made efforts to develop a double patterning process which enables to process a substrate by a single dry etching.

The inventors have discovered that a double patterning process capable of reducing the pitch between patterns to one half can be practiced by applying a first positive resist material, forming a first resist pattern therein through exposure and development, coating a pattern-protecting film material (protective coating solution) comprising a silicon compound having an amino group and a hydrolysis reactive group, and applying heat to cure the pattern surface so as to be insoluble in alkaline developer and resist solution. Then a second resist material is applied thereon, and a second resist pattern is formed therein through exposure and development, for example, so that the second pattern is located in a space portion of the first pattern. Then the substrate can be processed by a single dry etching. The present invention is predicated on this discovery.

The invention relates to a pattern forming process using a hydrolyzable silane compound having an amino group to facilitate surface crosslinkage and cure of the first resist pattern while a second resist pattern need not be cured. Then, after formation of the second resist pattern, coating of the hydrolyzable silane compound is not necessarily needed.

Particularly when a positive resist material comprising a base polymer having recurring units capable of forming carboxyl groups upon elimination of acid labile groups is used, the amino-containing silane compound adsorbs to the carboxyl groups generated by partial deprotection of acid labile groups on the resist pattern surface. Hydrolytic condensation of the silane compound results in an extremely thin-film coating. That is, a freezing pattern which is more robust and insoluble in solvent and alkaline developer is formed. The coating resulting from hydrolytic reaction of silane is sufficiently hydrophilic to prevent penetration of the resist solvent. Preventing solvent penetration is effective in preventing the first resist pattern from being dissolved upon coating of the second resist. The amino groups segregated on the resist surface provide a function to neutralize the acid generated upon second exposure, thus preventing the first resist pattern from being dissolved in a developer after second exposure.

As used in the patterning process of the invention for insolubilizing the first resist pattern, the silane compound having at least one amino group and a hydrolysis reactive group is preferably a silane compound having the general formula (1) or (2).

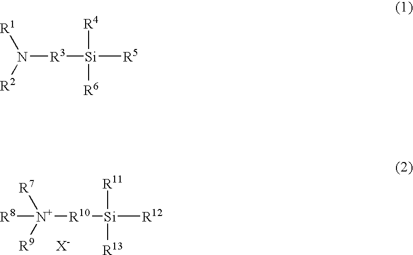

Herein R¹, R², R⁷, R⁸, and R⁹ are each independently hydrogen, a straight, branched or cyclic C₁-C₁₀ alkyl group which may have an amino, ether (—O—), ester (—COO—) or hydroxyl group, or a C₆-C₁₀ aryl, C₂-C₁₂ alkenyl or C₇-C₁₂ aralkyl group which may have an amino group, or R¹ and R², R⁷ and R⁸, R⁸ and R⁹, or R⁷ and R⁹ may bond together to form a ring with the nitrogen atom to which they are attached, e.g., pyrrolidino, morpholino, piperazino, and piperidino rings. R³ and R¹⁰ are each independently a straight, branched or cyclic C₁-C₁₂ alkylene group which may have an ether (—O—), ester (—COO—), thioether (—S—), phenylene or hydroxyl group. R⁴ to R⁶ and R¹¹ to R¹³ are each independently hydrogen, a C₁-C₆ alkyl, C₆-C₁₀ aryl, C₂-C₁₂ alkenyl, C₁-C₆ alkoxy, C₆-C₁₀ aryloxy, C₂-C₁₂ alkenyloxy, C₇-C₁₂ aralkyloxy or hydroxyl group, at least one of R⁴ to R⁶ and R¹¹ to R¹³ being alkoxy or hydroxyl. X⁻ is an anion such as hydroxyl, chloride, bromide, iodide, sulfate, nitrate, alkylcarboxylate, arylcarboxylate, alkylsulfonate, and arylsulfonate ions.

Examples of the silane compound having formula (1) include, but are not limited to,
3-aminopropyltrimethoxysilane, 3-aminopropyltriethoxysilane,
3-aminopropyltripropoxysilane,
3-aminopropyltriisopropoxysilane,
3-aminopropyltrihydroxysilane,
2-aminoethylaminomethyltrimethoxysilane,
2-aminoethylaminomethyltriethoxysilane,
2-aminoethylaminomethyltripropoxysilane,
2-aminoethylaminomethyltrihydroxysilane,
isopropylaminomethyltrimethoxysilane,
2-(2-aminoethylthio)ethyltrimethoxysilane,
allyloxy-2-aminoethylaminomethyldimethylsilane,
butylaminomethyltrimethoxysilane,
3-aminopropyldiethoxymethylsilane,
3-(2-aminoethylamino)propyldimethoxymethylsilane,
3-(2-aminoethylamino)propyltrimethoxysilane,
3-(2-aminoethylamino)propyltriethoxysilane,
3-(2-aminoethylamino)propyltriisopropoxysilane,
piperidinomethyltrimethoxysilane,
3-(allylamino)propyltrimethoxysilane,
4-methylpiperazinomethyltrimethoxysilane,
2-(2-aminoethylthio)ethyldiethoxymethylsilane,
morpholinomethyltrimethoxysilane,
4-acetylpiperazinomethyltrimethoxysilane,
cyclohexylaminotrimethoxysilane,
2-piperidinoethyltrimethoxysilane,
2-morpholinoethylthiomethyltrimethoxysilane,
dimethoxymethyl-2-piperidinoethylsilane,
3-morpholinopropyltrimethoxysilane,
dimethoxymethyl-3-piperazinopropylsilane,
3-piperazinopropyltrimethoxysilane,
3-butylaminopropyltrimethoxysilane,
3-dimethylaminopropyldiethoxymethylsilane,
2-(2-aminoethylthio)ethyltriethoxysilane,
3-[2-(2-aminoethylamino)ethylamino]propyltrimethoxysilane,
3-phenylaminopropyltrimethoxysilane,
2-aminoethylaminomethylbenzyloxydimethylsilane,
3-(4-acetylpiperazinopropyl)trimethoxysilane,
3-(3-methylpiperidinopropyl)trimethoxysilane,
3-(4-methylpiperidinopropyl)trimethoxysilane,
3-(2-methylpiperidinopropyl)trimethoxysilane,
3-(2-morpholinoethylthiopropyl)trimethoxysilane,
dimethoxymethyl-3-(4-methylpiperidinopropyl)silane,
3-cyclohexylaminopropyltrimethoxysilane,
3-benzylaminopropyltrimethoxysilane,
3-(2-piperidinoethylthiopropyl)trimethoxysilane,
3-hexamethyleneiminopropyltrimethoxysilane,
3-pyrrolidinopropyltrimethoxysilane,
3-(6-aminohexylamino)propyltrimethoxysilane,
3-(methylamino)propyltrimethoxysilane,
3-(ethylamino)-2-methylpropyltrimethoxysilane,
3-(butylamino)propyltrimethoxysilane,
3-(t-butylamino)propyltrimethoxysilane,
3-(diethylamino)propyltrimethoxysilane,
3-(cyclohexylamino)propyltrimethoxysilane,
3-anilinopropyltrimethoxysilane,
4-aminobutyltrimethoxysilane,
11-aminoundecyltrimethoxysilane,
11-aminoundecyltriethoxysilane,
11-(2-aminoethylamino)undecyltrimethoxysilane,
p-aminophenyltrimethoxysilane, m-aminophenyltrimethoxysilane,
3-(m-aminophenoxy)propyltrimethoxysilane,
2-(2-pyridyl)ethyltrimethoxysilane,
2-[(2-aminoethylamino)methylphenyl]ethyltrimethoxysilane,
diethylaminomethyltriethoxysilane,
3-[(3-acryloyloxy-2-hydroxypropyl)amino]propyltriethoxysilane,
3-(ethylamino)-2-methylpropyl(methyldiethoxysilane), and
3-[bis(hydroxyethyl)amino]propyltriethoxysilane.

The aminosilane compounds of formula (1) may be used alone or in a blend of two or more. Also useful are (partial) hydrolytic condensates of the aminosilane compounds.

Suitable aminosilane compounds of formula (1) further include reaction products of an oxirane-containing silane compound with an amine compound, as represented by the general formula (3).

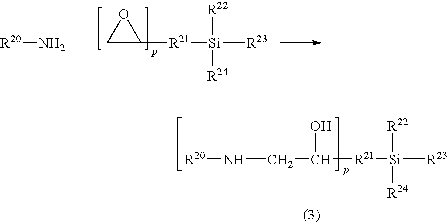

Herein R²⁰ is hydrogen, or a straight, branched or cyclic C₁-C₂₀ alkyl, C₆-C₁₀ aryl or C₂-C₁₂ alkenyl group which may have a hydroxyl, ether, ester or amino group. The subscript p is 1 or 2. When p is 1, R²¹ is a straight, branched or cyclic C₁-C₂₀ alkylene group which may have an ether, ester or phenylene group. When p is 2, R²¹ is the alkylene group with one hydrogen atom being eliminated. R²² to R²⁴ are each independently hydrogen, or a C₁-C₆ alkyl, C₆-C₁₀ aryl, C₂-C₁₂ alkenyl, C₁-C₆ alkoxy, C₆-C₁₀ aryloxy, C₂-C₁₂ alkenyloxy, C₇-C₁₂ aralkyloxy or hydroxyl group, at least one of R²² to R²⁴ being alkoxy or hydroxyl.

Particularly when an aminosilane compound of formula (1) wherein R¹ is hydrogen, i.e., aminosilane having a secondary amino group or an aminosilane compound of formula (1) wherein both R¹ and R² are hydrogen, i.e., aminosilane having a primary amino group is admixed with an oxirane-containing silane compound, a silane compound having the general formula (4) forms through the reaction shown below, for example. When a mixture of a primary or secondary amino group-containing aminosilane and an oxirane-containing silane compound is used, the silane compound of formula (4) adsorbs on the resist surface.

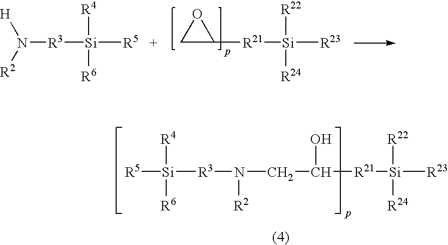

Herein, R² to R⁶, R²¹ to R²⁴, and p are as defined above.

The oxirane-containing silane compound used herein will be described later. An oxetane-containing silane compound may be used instead of the oxirane. The desired amine compounds are primary or secondary. Suitable primary amine compounds include ammonia, methylamine, ethylamine, n-propylamine, isopropylamine, n-butylamine, isobutylamine, sec-butylamine, tert-butylamine, pentylamine, tert-amylamine, cyclopentylamine, hexylamine, cyclohexylamine, heptylamine, octylamine, nonylamine, decylamine, dodecylamine, cetylamine, methylenediamine, ethylenediamine, tetraethylenepentamine, ethanolamine, N-hydroxyethylethylamine, and N-hydroxypropylethylamine. Suitable secondary aliphatic amines include dimethylamine, diethylamine, di-n-propylamine, diisopropylamine, di-n-butylamine, diisobutylamine, di-sec-butylamine, dipentylamine, dicyclopentylamine, dihexylamine, dicyclohexylamine, diheptylamine, dioctylamine, dinonylamine, didecylamine, didodecylamine, dicetylamine, N,N-dimethylmethylenediamine, N,N-dimethylethylenediamine, and N,N-dimethyltetraethylenepentamine.

The aminosilane compound may be blended with another silane compound. Blends of aminosilanes and epoxy-containing silanes are described in, for example, JP-A 2005-248169.

Examples of the silane compound having an ammonium salt represented by formula (2) include, but are not limited to, N-trimethoxysilylpropyl-N,N,N-trimethylammonium hydroxide, N-triethoxysilylpropyl-N,N,N-trimethylammonium hydroxide, N,N,N-trimethyl-N-(tripropoxysilylpropyl)ammonium hydroxide, N,N,N-tributyl-N-(trimethoxysilylpropyl)ammonium hydroxide, N,N,N-triethyl-N-(trimethoxysilylpropyl)ammonium hydroxide, N-trimethoxysilylpropyl-N,N,N-tripropylammonium hydroxide, N-(2-trimethoxysilyl)benzyl-N,N,N-trimethylammonium hydroxide, N-trimethoxysilylpropyl-N,N,N-trimethylammonium hydroxide, and N-trimethoxysilylpropyl-N,N-dimethyl-N-tetradecylammonium hydroxide. In addition to the hydroxide ion described just above, examples of the anion X⁻ include halide ions such as chloride and bromide, and anions derived from acetic acid, formic acid, oxalic acid, citric acid, nitric acid, sulfonic acid, methanesulfonic acid, trifluoromethanesulfonic acid, tosylic acid, and benzenesulfonic acid. In order that ammonium ions adsorb on the resist surface via anion exchange with carboxyl groups on the resist surface, the anion X⁻ is preferably a weak acid or base anion, and most preferably hydroxy anion.

A silane compound having the general formula (5) may be used in blend with the aminosilane or ammonium salt-containing silane compound of formula (1) or (2).

R³¹ₘ₁R³²ₘ₂R³³ₘ₃Si(OR)₍₄₋ₘ₁₋ₘ₂₋ₘ₃₎ (5)

Herein R is C₁-C₃ alkyl, R³¹, R³² and R³³ which may be the same or different are each hydrogen or a C₁-C₃₀ monovalent organic group, m1, m2 and m3 are each equal to 0 or 1, and m1+m2+m3 is 0 to 3, preferably 0 or 1.

As used herein, the term “organic group” refers to a group comprising carbon and further hydrogen, which may additionally contain nitrogen, oxygen, sulfur, silicon or the like. Suitable organic groups represented by R³¹, R³² and R³³ include unsubstituted monovalent hydrocarbon groups such as straight, branched or cyclic alkyl, alkenyl, alkynyl, aryl and aralkyl groups, substituted forms of these groups in which one or more hydrogen are substituted by epoxy, alkoxy, hydroxy or the like, organic groups separated by —O—, —CO—, —OCO—, or —OCOO—, and organic groups containing a silicon-silicon bond to be described later.

In the monomer of formula (5), preferred examples of R³¹, R³² and R³³ include hydrogen, alkyl groups such as methyl, ethyl, n-propyl, isopropyl, n-butyl, isobutyl, sec-butyl, t-butyl, n-pentyl, 2-ethylbutyl, 3-ethylbutyl, 2,2-diethylpropyl, cyclopentyl, n-hexyl, cyclohexyl, octyl, decyl, dodecyl, octadecyl, and perfluorooctyl, alkenyl groups such as vinyl and allyl, alkynyl groups such as ethynyl, as well as photo-absorptive groups including aryl groups such as phenyl and tolyl, and aralkyl groups such as benzyl and phenethyl.

Examples of the tetraalkoxysilane monomer of formula (5) wherein m1=0, m2=0 and m3=0 include tetramethoxysilane, tetraethoxysilane, tetra-n-propoxysilane, and tetraisopropoxysilane. Of these, tetramethoxysilane and tetraethoxysilane are preferred.

Examples of the trialkoxysilane monomer of formula (5) wherein m1=1, m2=0 and m3=0 include trimethoxysilane, triethoxysilane, tripropoxysilane, triisopropoxysilane, methyltrimethoxysilane, methyltriethoxysilane, methyltripropoxysilane, methyltriisopropoxysilane, ethyltrimethoxysilane, ethyltriethoxysilane, ethyltri-n-propoxysilane, ethyltriisopropoxysilane, vinyltrimethoxysilane, vinyltriethoxysilane, vinyltripropoxysilane, vinyltriisopropoxysilane, n-propyltrimethoxysilane, n-propyltriethoxysilane, n-propyltripropoxysilane, n-propyltriisopropoxysilane, isopropyltrimethoxysilane, isopropyltriethoxysilane, isopropyltripropoxysilane, isopropyltriisopropoxysilane, n-butyltrimethoxysilane, n-butyltriethoxysilane, n-butyltripropoxysilane, n-butyltriisopropoxysilane, s-butyltrimethoxysilane, s-butyltriethoxysilane, s-butyltripropoxysilane, s-butyltriisopropoxysilane, t-butyltrimethoxysilane, t-butyltriethoxysilane, t-butyltripropoxysilane, t-butyltriisopropoxysilane, cyclopropyltrimethoxysilane, cyclopropyltriethoxysilane, cyclopropyltripropoxysilane, cyclopropyltriisopropoxysilane, cyclobutyltrimethoxysilane, cyclobutyltriethoxysilane, cyclobutyltripropoxysilane, cyclobutyltriisopropoxysilane, cyclopentyltrimethoxysilane, cyclopentyltriethoxysilane, cyclopentyltripropoxysilane, cyclopentyltriisopropoxysilane, cyclohexyltrimethoxysilane, cyclohexyltriethoxysilane, cyclohexyltripropoxysilane, cyclohexyltriisopropoxysilane, cyclohexenyltrimethoxysilane, cyclohexenyltriethoxysilane, cyclohexenyltripropoxysilane, cyclohexenyltriisopropoxysilane, cyclohexenylethyltrimethoxysilane, cyclohexenylethyltriethoxysilane, cyclohexenylethyltripropoxysilane, cyclohexenylethyltriisopropoxysilane, cyclooctanyltrimethoxysilane, cyclooctanyltriethoxysilane, cyclooctanyltripropoxysilane, cyclooctanyltriisopropoxysilane, cyclopentadienylpropyltrimethoxysilane, cyclopentadienylpropyltriethoxysilane, cyclopentadienylpropyltripropoxysilane, cyclopentadienylpropyltriisopropoxysilane, bicycloheptenyltrimethoxysilane, bicycloheptenyltriethoxysilane, bicycloheptenyltripropoxysilane, bicycloheptenyltriisopropoxysilane, bicycloheptyltrimethoxysilane, bicycloheptyltriethoxysilane, bicycloheptyltripropoxysilane, bicycloheptyltriisopropoxysilane, adamantyltrimethoxysilane, adamantyltriethoxysilane, adamantyltripropoxysilane, and adamantyltriisopropoxysilane. Suitable photo-absorptive monomers include phenyltrimethoxysilane, phenyltriethoxysilane, phenyltripropoxysilane, phenyltriisopropoxysilane, benzyltrimethoxysilane, benzyltriethoxysilane, benzyltripropoxysilane, benzyltriisopropoxysilane, tolyltrimethoxysilane, tolyltriethoxysilane, tolyltripropoxysilane, tolyltriisopropoxysilane, phenethyltrimethoxysilane, phenethyltriethoxysilane, phenethyltripropoxysilane, phenethyltriisopropoxysilane, naphthyltrimethoxysilane, naphthyltriethoxysilane, naphthyltripropoxysilane, and naphthyltriisopropoxysilane.

Examples of the dialkoxysilane monomer of formula (5) wherein m1=1, m2=1 and m3=0 include dimethyldimethoxysilane, dimethyldiethoxysilane, methylethyldimethoxysilane, methylethyldiethoxysilane, dimethyldipropoxysilane, dimethyldiisopropoxysilane, diethyldimethoxysilane, diethyldiethoxysilane, diethyldipropoxysilane, diethyldiisopropoxysilane, dipropyldimethoxysilane, dipropyldiethoxysilane, dipropyldipropoxysilane, dipropyldiisopropoxysilane, diisopropyldimethoxysilane, diisopropyldiethoxysilane, diisopropyldipropoxysilane, diisopropyldiisopropoxysilane, dibutyldimethoxysilane, dibutyldiethoxysilane, dibutyldipropoxysilane, dibutyldiisopropoxysilane, di-s-butyldimethoxysilane, di-s-butyldiethoxysilane, di-s-butyldipropoxysilane, di-s-butyldiisopropoxysilane, di-t-butyldimethoxysilane, di-t-butyldiethoxysilane, di-t-butyldipropoxysilane, di-t-butyldiisopropoxysilane, dicyclopropyldimethoxysilane, dicyclopropyldiethoxysilane, dicyclopropyldipropoxysilane, dicyclopropyldiisopropoxysilane, dicyclobutyldimethoxysilane, dicyclobutyldiethoxysilane, dicyclobutyldipropoxysilane, dicyclobutyldiisopropoxysilane, dicyclopentyldimethoxysilane, dicyclopentyldiethoxysilane, dicyclopentyldipropoxysilane, dicyclopentyldiisopropoxysilane, dicyclohexyldimethoxysilane, dicyclohexyldiethoxysilane, dicyclohexyldipropoxysilane, dicyclohexyldiisopropoxysilane, dicyclohexenyldimethoxysilane, dicyclohexenyldiethoxysilane, dicyclohexenyldipropoxysilane, dicyclohexenyldiisopropoxysilane, dicyclohexenylethyldimethoxysilane, dicyclohexenylethyldiethoxysilane, dicyclohexenylethyldipropoxysilane, dicyclohexenylethyldiisopropoxysilane, dicyclooctanyldimethoxysilane, dicyclooctanyldiethoxysilane, dicyclooctanyldipropoxysilane, dicyclooctanyldiisopropoxysilane, dicyclopentadienylpropyldimethoxysilane, dicyclopentadienylpropyldiethoxysilane, dicyclopentadienylpropyldipropoxysilane, dicyclopentadienylpropyldiisopropoxysilane, bisbicycloheptenyldimethoxysilane, bisbicycloheptenyldiethoxysilane, bisbicycloheptenyldipropoxysilane, bisbicycloheptenyldiisopropoxysilane, bisbicycloheptyldimethoxysilane, bisbicycloheptyldiethoxysilane, bisbicycloheptyldipropoxysilane, bisbicycloheptyldiisopropoxysilane, bisadamantyldimethoxysilane, bisadamantyldiethoxysilane, bisadamantyldipropoxysilane, and bisadamantyldiisopropoxysilane. Suitable photo-absorptive monomers include diphenyldimethoxysilane, diphenyldiethoxysilane, methylphenyldimethoxysilane, methylphenyldiethoxysilane, diphenyldipropoxysilane, and diphenyldiisopropoxysilane.

Examples of the monoalkoxysilane monomer of formula (5) wherein m1=1, m2=1 and m3=1 include trimethylmethoxysilane, trimethylethoxysilane, dimethylethylmethoxysilane, and dimethylethylethoxysilane. Suitable photo-absorptive monomers include dimethylphenylmethoxysilane, dimethylphenylethoxysilane, dimethylbenzylmethoxysilane, dimethylbenzylethoxysilane, dimethylphenethylmethoxysilane, and dimethylphenethylethoxysilane.

Other examples of the organic group represented by R³¹, R³² and R³³ include organic groups having at least one carbon-oxygen single bond or carbon-oxygen double bond. Typical are those organic groups having at least one group selected from among epoxy, ester, alkoxy, and hydroxy groups. The organic groups having at least one carbon-oxygen single bond or carbon-oxygen double bond encompassed within formula (5) include, for example, those of the following general formula (6).

(P-Q₁-(S₁)ᵥ₁-Q₂)ᵤ-(T)ᵥ₂-Q₃-(S₂)ᵥ₃-Q₄- (6)

Herein P is hydrogen, hydroxyl, epoxy ring of the formula:

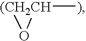

C₁-C₄ alkoxy, C₂-C₆ alkylcarbonyloxy, or C₂-C₆ alkylcarbonyl group. Q₁, Q₂, Q₃ and Q₄ are each independently —C_{q}H_{(2q-r)}Pᵣ— wherein P is as defined above, r is an integer of 0 to 3, q is an integer of 0 to 10, with the proviso that q=0 means a single bond. The subscript u is an integer of 0 to 3. S₁ and S₂ are each independently —O—, —CO—, —OCO—, —COO— or —OCOO—. The subscripts v1, v2 and v3 are each independently 0 or 1. T is a divalent alicyclic or aromatic ring group which may contain a heteroatom such as oxygen. Examples of the optionally heteroatom-containing alicyclic or aromatic ring represented by T are shown below. While the positions on T at which T bonds with Q₂ and Q₃ are not particularly limited, T may be selected in accordance with reactivity associated with steric factors and availability of commercial reagents used in reaction.

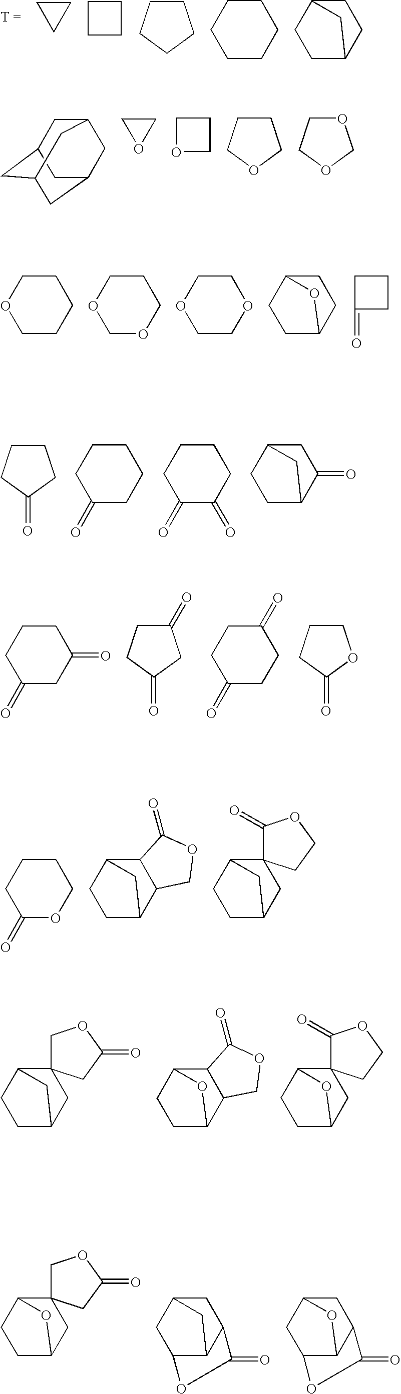

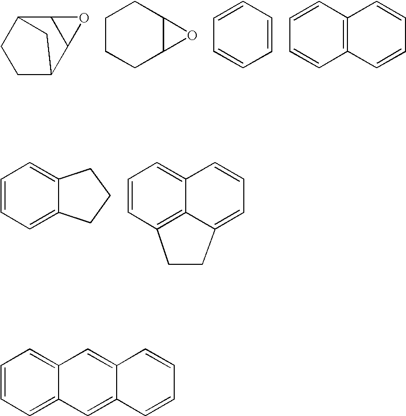

Preferred examples of the organic groups having at least one carbon-oxygen single bond or carbon-oxygen double bond encompassed within formula (5) are given below. Note that in the following formulae, (Si) is depicted to indicate the position of each group bonding to silicon.

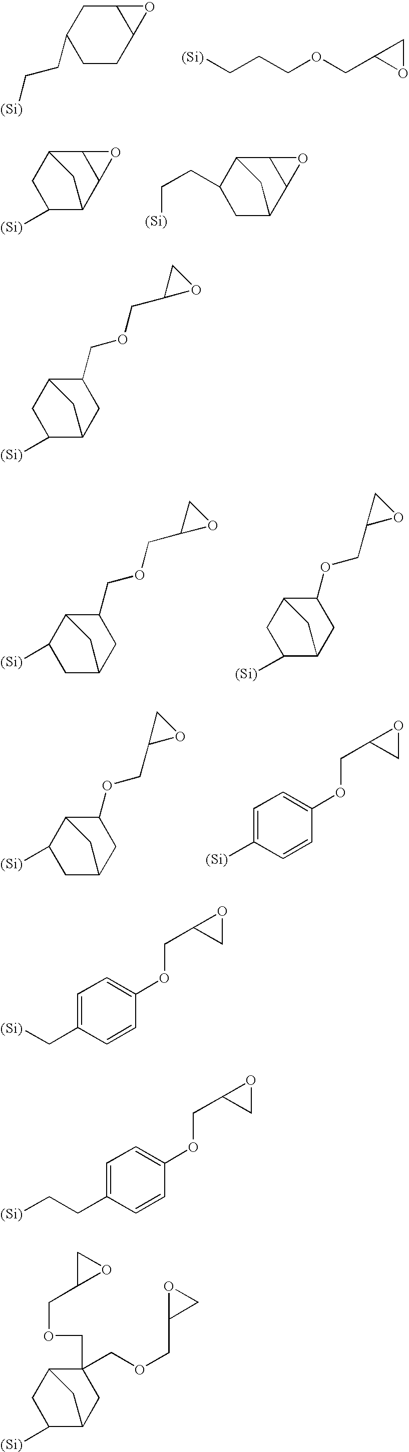

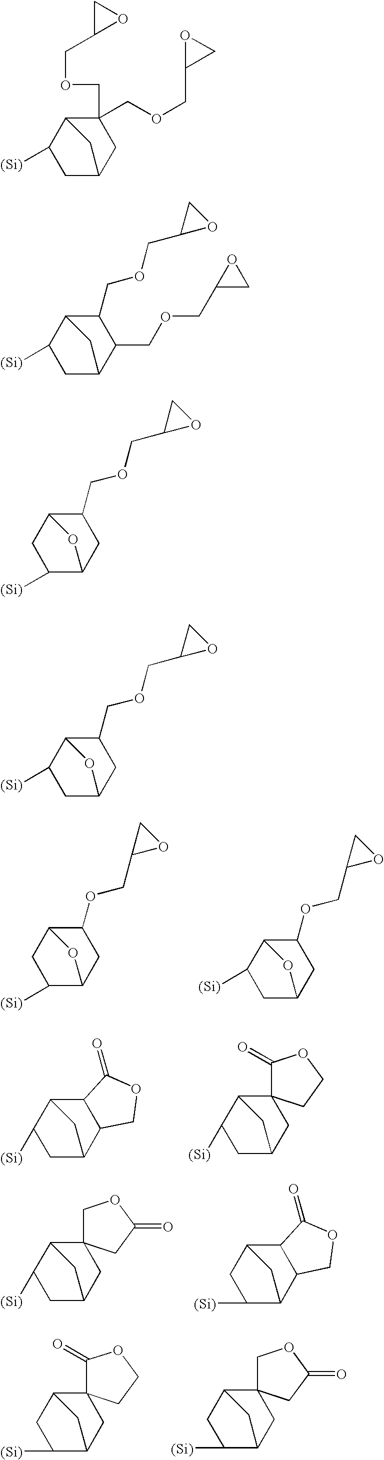

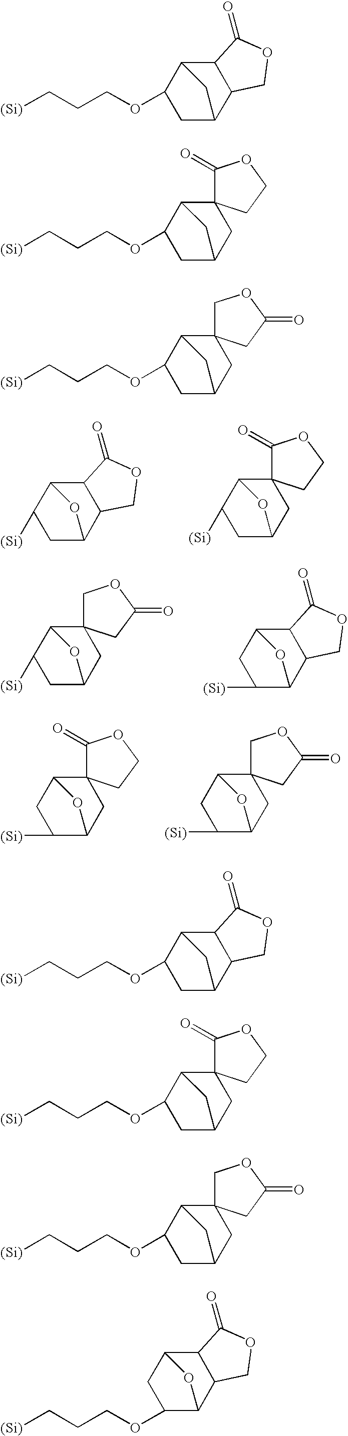

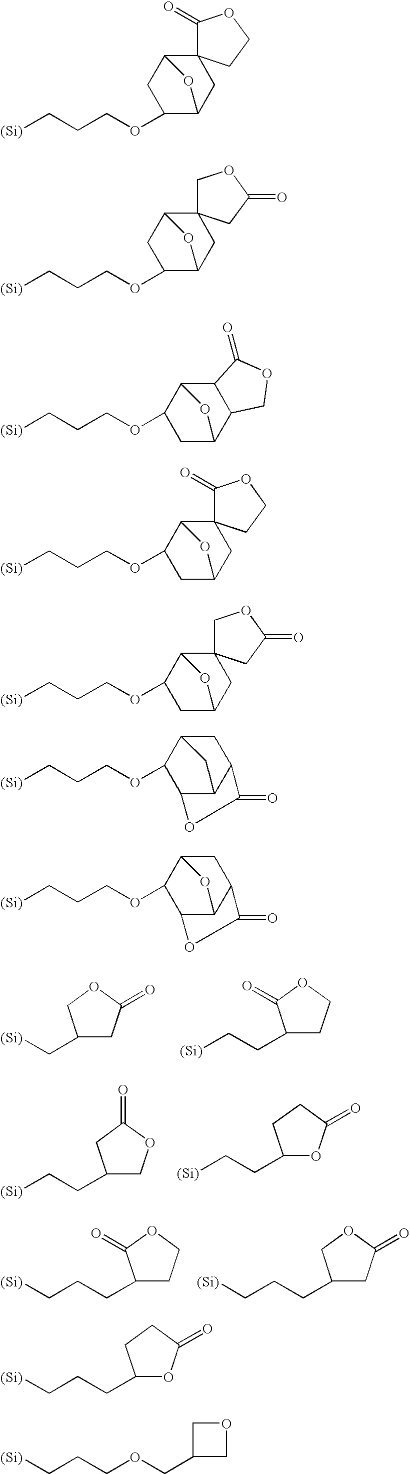

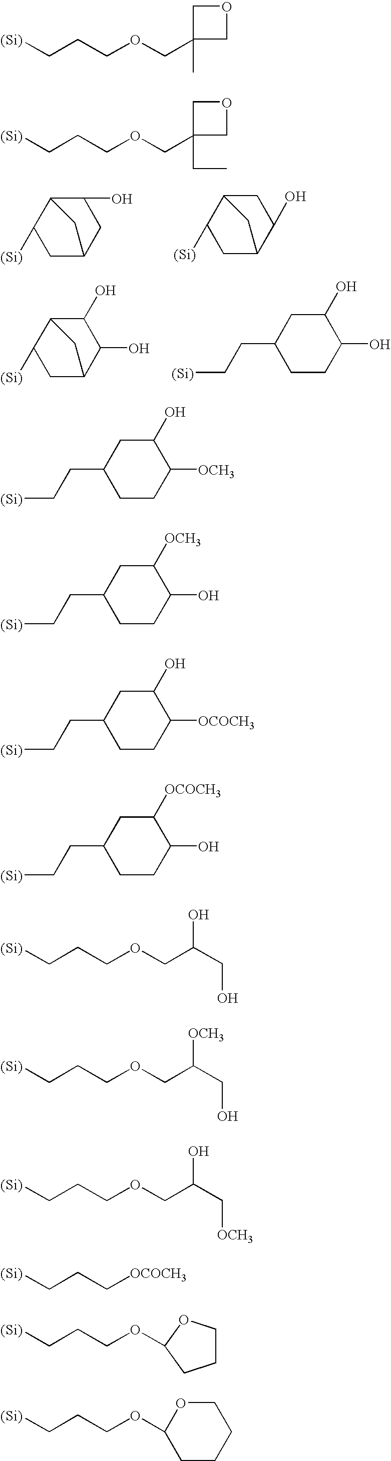

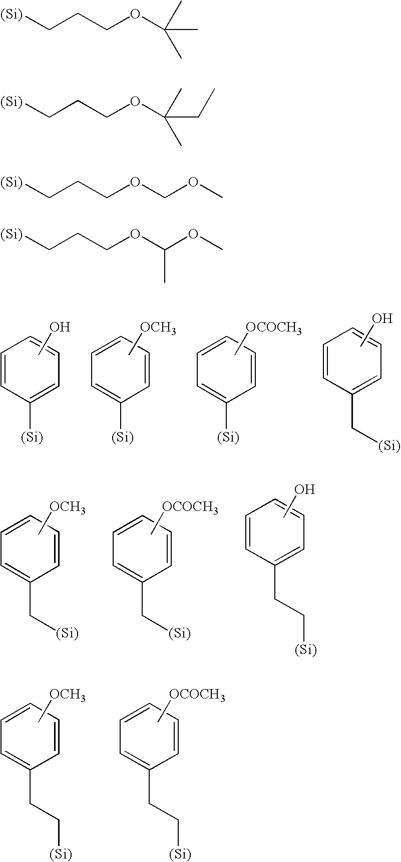

Further examples of the organic group represented by R³¹, R³² and R³³ include organic groups having a silicon-silicon bond, examples of which are given below.

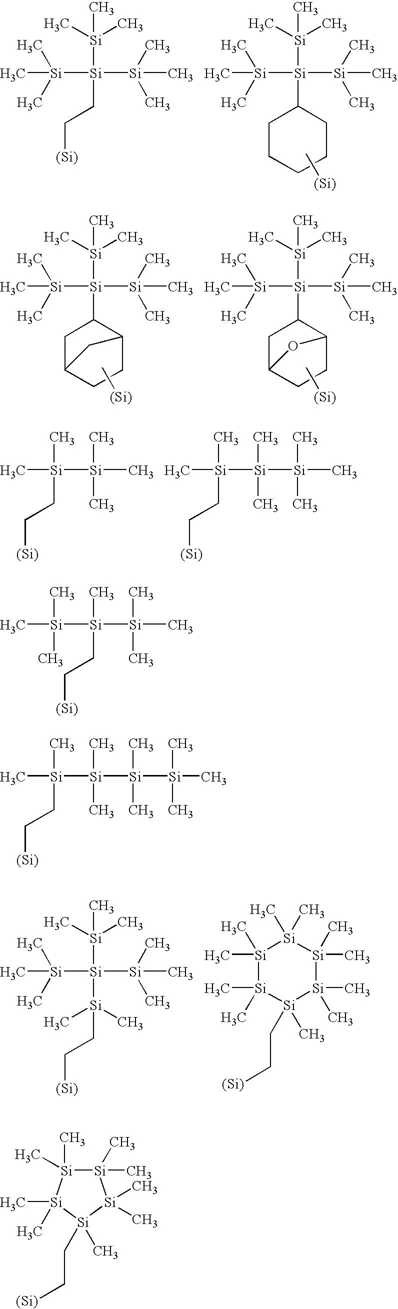

As used in the patterning process of the invention, the aminosilane compound may be admixed with a titanium compound as described in JP-A 2006-65035, in order to accelerate condensation reaction of the silane.

As used herein, the pattern protective coating material (protective coating solution) comprises a silicon compound having an amino group and a hydrolysis reactive group as defined above, and optionally, a silane compound of formula (5). In the patterning process of the invention, the silicon compound having at least one amino group and a hydrolysis reactive group is preferably dissolved in a solvent selected from alcohols of 3 to 8 carbon atoms, water, and mixtures thereof. Since the base polymer in the positive resist material is not soluble in alcohols of 3 to 8 carbon atoms, formation of an intermixing layer with the resist pattern is substantially prevented. Suitable alcohols of 3 to 8 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-amyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-diethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, n-octanol, and cyclohexanol.

To prevent intermixing with the resist film, another solvent may be used in admixture with the foregoing alcohol. Examples of the other solvent include water, heavy water, diisobutyl ether, diisopentyl ether, dipentyl ether, methyl cyclopentyl ether, methyl cyclohexyl ether, decane, toluene, xylene, anisole, hexane, cyclohexane, 2-fluoroanisole, 3-fluoroanisole, 4-fluoroanisole, 2,3-difluoroanisole, 2,4-difluoroanisole, 2,5-difluoroanisole, 5,8-difluoro-1,4-benzodioxane, 2,3-difluorobenzyl alcohol, 1,3-difluoro-2-propanol, 2′,4′-difluoropropiophenone, 2,4-difluorotoluene, trifluoroacetoaldehyde ethyl hemiacetal, trifluoroacetamide, trifluoroethanol, 2,2,2-trifluoroethyl butyrate, ethyl heptafluorobutyrate, ethyl heptafluorobutylacetate, ethyl hexafluoroglutarylmethyl, ethyl-3-hydroxy-4,4,4-trifluorobutyrate, ethyl 2-methyl-4,4,4-trifluoroacetoacetate, ethyl pentafluorobenzoate, ethyl pentafluoropropionate, ethyl pentafluoropropynylacetate, ethyl perfluorooctanoate, ethyl 4,4,4-trifluoroacetoacetate, ethyl 4,4,4-trifluorobutyrate, ethyl 4,4,4-trifluorocrotonate, ethyl trifluorosulfonate, ethyl 3-(trifluoromethyl)butyrate, ethyl trifluoropilvate, S-ethyl trifluoroacetate, fluorocyclohexane, 2,2,3,3,4,4,4-heptafluoro-1-butanol, 1,1,1,2,2,3,3-heptafluoro-7,7-dimethyl-4,6-octanedione, 1,1,1,3,5,5,5-heptafluoropentane-2,4-dione, 3,3,4,4,5,5,5-heptafluoro-2-pentanol, 3,3,4,4,5,5,5-heptafluoro-2-pentanone, isopropyl 4,4,4-trifluoroacetoacetate, methyl perfluorodecanoate, methyl perfluoro(2-methyl-3-oxahexanoate), methyl perfluorononanoate, methyl perfluorooctanoate, methyl 2,3,3,3-tetrafluoropropionate, methyl trifluoroacetoacetate, 1,1,1,2,2,6,6,6-octafluoro-2,4-hexanedione, 2,2,3,3,4,4,5,5-octafluoro-1-pentanol, 1H,1H,2H,2H-perfluoro-1-decanol, perfluoro(2,5-dimethyl-3,6-dioxane anionic)acid methyl ester, 2H-perfluoro-5-methyl-3,6-dioxanonane, 1H,1H,2H,3H,3H-perfluorononane-1,2-diol, 1H,1H,9H-perfluoro-1-nonanol, 1H,1H-perfluorooctanol, 1H,1H,2H,2H-perfluorooctanol, 2H-perfluoro-5,8,11,14-tetramethyl-3,6,9,12,15-pentaoxa-octadecane, perfluorotributylamine, perfluorotrihexylamine, perfluoro-2,5,8-trimethyl-3,6,9-trioxadodecanoic acid methyl ester, perfluorotripentylamine, perfluorotripropylamine, 1H,1H,2H,3H,3H-perfluoroundecane-1,2-diol, trifluorobutanol, 1,1,1-trifluoro-5-methyl-2,4-hexanedione, 1,1,1-trifluoro-2-propanol, 3,3,3-trifluoro-1-propanol, 1,1,1-trifluoro-2-propyl acetate, perfluorobutyltetrahydrofuran, perfluorodecalin, perfluoro(1,2-dimethylcyclohexane), perfluoro(1,3-dimethylcyclohexane), propylene glycol trifluoromethyl ether acetate, propylene glycol methyl ether trifluoromethyl acetate, butyl trifluoromethylacetate, methyl 3-trifluoromethoxypropionate, perfluorocyclohexanone, propylene glycol trifluoromethyl ether, butyl trifluoroacetate, 1,1,1-trifluoro-5,5-dimethyl-2,4-hexanedione, 1,1,1,3,3,3-hexafluoro-2-propanol, 1,1,1,3,3,3-hexafluoro-2-methyl-2-propanol, 2,2,3,4,4,4-hexafluoro-1-butanol, 2-trifluoromethyl-2-propanol, 2,2,3,3-tetrafluoro-1-propanol, 3,3,3-trifluoro-1-propanol, and 4,4,4-trifluoro-1-butanol, alone or in admixture.

An amino-containing compound may also be used as the solvent. The amino group may be primary, secondary or tertiary. The compound may have more than one amino group in a molecule and may have a hydroxy group or an aromatic ring. Exemplary amino-containing compounds include ammonia, methylamine, ethylamine, n-propylamine, isopropylamine, n-butylamine, s-butylamine, isobutylamine, t-butylamine, 1-ethylbutylamine, n-pentylamine, s-pentylamine, isopentylamine, cyclopentylamine, t-amylamine, n-hexylamine, cyclohexylamine, dimethylamine, diethylamine, dipropylamine, dibutylamine, trimethylamine, triethylamine, tripropylamine, tributylamine, triethanolamine, triisopropanolamine, tri-n-propanolamine, tributylamine, N,N-dimethylcyclohexylamine, N,N-dimethylpentylamine, N,N-dimethylbutylamine, aniline, toluidine, xylidine, 1-naphthylamine, diphenylamine, N,N-dimethylaniline, pyridine, piperidine, piperazine, 1,8-diazabicyclo[5.4.0]-7-undecene (DBU), 1,5-diazabicyclo[4.3.0]-5-nonene (DBN), ethylenediamine, propylenediamine, butylenediamine, 1,3-cyclopentanediamine, 1,4-cyclohexanediamine, N,N,N′,N′-tetramethylethylenediamine, p-phenylenediamine, 1,3-diaminopropane, 1,4-diaminobutane, 1,5-diaminopentane, 1,6-diaminohexane, 1,8-diaminooctane, 1,3-diaminopentane, 1,3-diamino-2-propanol, 2-(2-aminoethylamino)ethanol, and polyethyleneimine. The amino-containing compound may be admixed with the aforementioned water, alcohol, ether and fluorinated solvents.

A mixture of water and heavy water serves to accelerate hydrolytic condensation reaction of the amino-containing silane compound after coating. Alternatively, prior to coating, water and heavy water may be added to the amino-containing silane compound so that hydrolytic condensation takes place to form an oligomer of the silane compound. The oligomeric silane compound may have the structure of ladder or polyhedral silsesquioxane.

In the pattern protective coating material (or protective coating solution) comprising a silicon compound having at least one amino group and a hydrolysis reactive group, the alcohol of 3 to 8 carbon atoms is preferably contained in an amount of at least 10% by weight, and more preferably 30 to 99.9999% by weight. In the pattern protective coating material, the silicon compound having at least one amino group and a hydrolysis reactive group is preferably contained in an amount of 0.0001 to 10% by weight, and more preferably 0.001 to 5% by weight. In the pattern protective coating material, water is preferably contained in an amount of at least 0.0001% by weight, and more preferably 0.001 to 98% by weight. The silane compound of formula (5) is preferably contained in an amount of 0 to 10% by weight.

In the pattern protective coating material (or pattern surface coating composition) comprising a silicon compound having at least one amino group and a hydrolysis reactive group, a binder resin may be blended. The binder resin to be blended must be miscible with the aforementioned water, alcohol, ether or fluorinated solvents and amine solvents. The binder resin is preferably a water-soluble resin, which is expected, when a second resist material comprising a solvent is applied, to prevent penetration of the solvent into the first resist pattern. The binder resin, when blended, ensures that a coating of the protective coating material on the first resist pattern becomes more uniform in thickness.

Examples of the binder resin which can be blended include polyvinyl pyrrolidone, polyethylene oxide, amylose, dextran, cellulose, pluran, polyacrylic acid, polymethacrylic acid, polymethacrylic acid hydroxyethyl, polyacrylic acid amide, polymethacrylic acid amide, N-substituted polyacrylic acid amide, N-substituted polymethacrylic acid amide, poly(acrylic acid-co-dimethylaminoethyl), poly(methacrylic acid-co-dimethylaminoethyl), poly(acrylic acid-co-diethylaminoethyl), poly(methacrylic acid-co-diethylaminoethyl), polyvinyl alcohol, partially butyral polyvinyl alcohol, methyl cellulose, hydroxyethylmethyl cellulose, hydroxypropylmethyl cellulose, polyvinyl pyridine, polyvinyl imidazole, poly(2-ethyl-2-oxazoline), poly(2-isopropenyloxazoline), and copolymers thereof with other monomers. The binder resin is preferably blended in an amount of 1 to 1,000 parts by weight per 100 parts by weight of the silicon compound having an amino group and a hydrolysis reactive group.

According to the process of the invention, a first positive resist pattern is formed via exposure and development, then a pattern protective coating material comprising a silicon compound having at least one amino group and a hydrolysis reactive group and water and/or a monohydric alcohol of 3 to 8 carbon atoms is coated on the first resist pattern, and baked. If desired, the extra silicon compound is removed using water, a monohydric alcohol of 3 to 8 carbon atoms or alkaline developer or a mixture thereof. Further baking may be effected for the purpose of accelerating crosslinking of the silicon compound. On the protective coating, a second positive resist material is coated over the substrate to form a second resist coating, which is heat treated and then exposed to high-energy radiation, heat treated again and developed with a developer.

During the exposure step to form the second resist pattern, the first resist pattern is also irradiated with radiation. Since the first resist pattern must be maintained even after the second development step, the insolubilized film formed on the resist pattern surface according to the resist pattern forming process of the invention must be insoluble in alkaline developer as well.

It is believed that when the silicon compound having at least one amino group and a hydrolysis reactive group is used in the resist pattern insolubilizing film, the amino group or quaternary ammonium salt of the silane compound adsorbs to the resist surface, thereby rendering the resist surface hydrophilic. Baking after coating accelerates adsorption on the resist surface, and hydrolytic condensation reaction of hydrolyzable groups to induce crosslinking. The hydrophilicity and crosslinkage of the resist surface prevents the solvent from penetrating into the resist film during coating of the second resist material. Upon the second exposure, an acid is generated within the first resist pattern, but the acid generated is neutralized with the amino groups adsorbed on the resist surface, suppressing the progress of deprotection reaction within the first resist pattern and thus preventing the first resist pattern from being dissolved in the developer used in the second development.

As compared with the prior art approach of insolubilizing the resist pattern by covering the resist pattern with a crosslinkable high-molecular weight polymer, the patterning process of the invention has the advantages that a film covering the resist pattern is very thin and the resist pattern undergoes little size variation after insolubilizing treatment, because the aminosilane used herein has a very small molecular size.

### Resist Material

Each of the first and second resist materials used herein comprises a base polymer which is typically a polymer obtained by copolymerization of recurring units having an acid labile group with recurring units having an adhesive group. The recurring units having an acid labile group are described in U.S. Pat. No. 7,537,880 or JP-A 2008-111103, paragraphs [0083] to [0104] and [0114] to [0117]. The recurring units having an adhesive group are typically recurring units having a lactone, hydroxy, carboxyl, cyano or carbonyl group and specifically described in JP-A 2008-111103, paragraphs [0107] to [0112]. In order that the resist material function as a chemically amplified positive resist material, the resist material may comprise an acid generator, for example, a compound capable of generating an acid in response to actinic light or radiation, generally referred to as “photoacid generator.” The photoacid generator may be any compound capable of generating an acid upon exposure to high-energy radiation. Suitable photoacid generators include sulfonium salt, iodonium salt, sulfonyldiazomethane, N-sulfonyloxyimide, and oxime-O-sulfonate acid generators, which may be used alone or in admixture. Examples of the acid generator are described in JP-A 2008-111103, paragraphs [0122] to [0142].

The resist material used herein may further comprise one or more component selected from organic solvents, basic compounds, dissolution regulators, surfactants, and acetylene alcohols. Exemplary organic solvents are described in JP-A 2008-111103, paragraphs [0144] to [0145]; exemplary basic compounds in paragraphs [0146] to [0164]; and exemplary surfactants in paragraphs [0165] to [0166]. Exemplary dissolution regulators are described in US 2008090172 A1 or JP-A 2008-122932, paragraphs [0155] to [0178]; and exemplary acetylene alcohols in paragraphs [0179] to [0182].

The foregoing components may be compounded in standard amounts. For example, 0.1 to 50 parts by weight of the acid generator, 100 to 10,000 parts by weight of the organic solvent, and 0.001 to 10 parts by weight of the basic compound may be compounded per 100 parts by weight of the base resin.

### Process

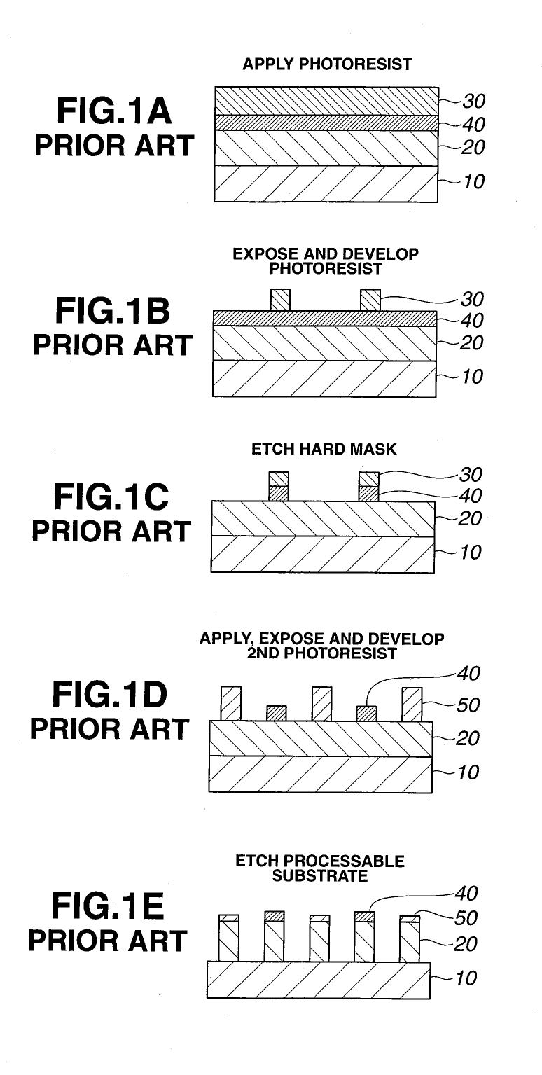

Now, the double patterning process is described. FIGS. 1 to 3 illustrate prior art double patterning processes.

Referring to FIG. 1, one exemplary double patterning process 1 is illustrated. A photoresist film 30 is coated and formed on a processable substrate 20 on a substrate 10. To prevent the photoresist pattern from collapsing, the technology intends to reduce the thickness of photoresist film. One approach taken to compensate for a lowering of etch resistance of thinner film is to process the processable substrate using a hard mask. The double patterning process illustrated in FIG. 1 uses a multilayer coating in which a hard mask 40 is laid between the photoresist film 30 and the processable substrate 20 as shown in FIG. 1-A. In the double patterning process, the hard mask is not always necessary, and an underlayer film in the form of a carbon film and a silicon-containing intermediate film may be laid instead of the hard mask, or an organic antireflective coating may be laid between the hard mask and the photoresist film. The hard mask used herein may be of SiO₂, SiN, SiON or p-Si, for example. The resist material used in double patterning process 1 is a positive resist composition. In the process, the resist film 30 is exposed and developed (FIG. 1-B), the hard mask 40 is then dry etched (FIG. 1-C), the photoresist film is stripped, and a second photoresist film 50 is coated, formed, exposed, and developed (FIG. 1-D). Then the processable substrate 20 is dry etched (FIG. 1-E). Since this etching is performed using the hard mask pattern and the second photoresist pattern as a mask, variations occur in the pattern size after etching of the processable substrate due to a difference in etch resistance between hard mask 40 and photoresist film 50.

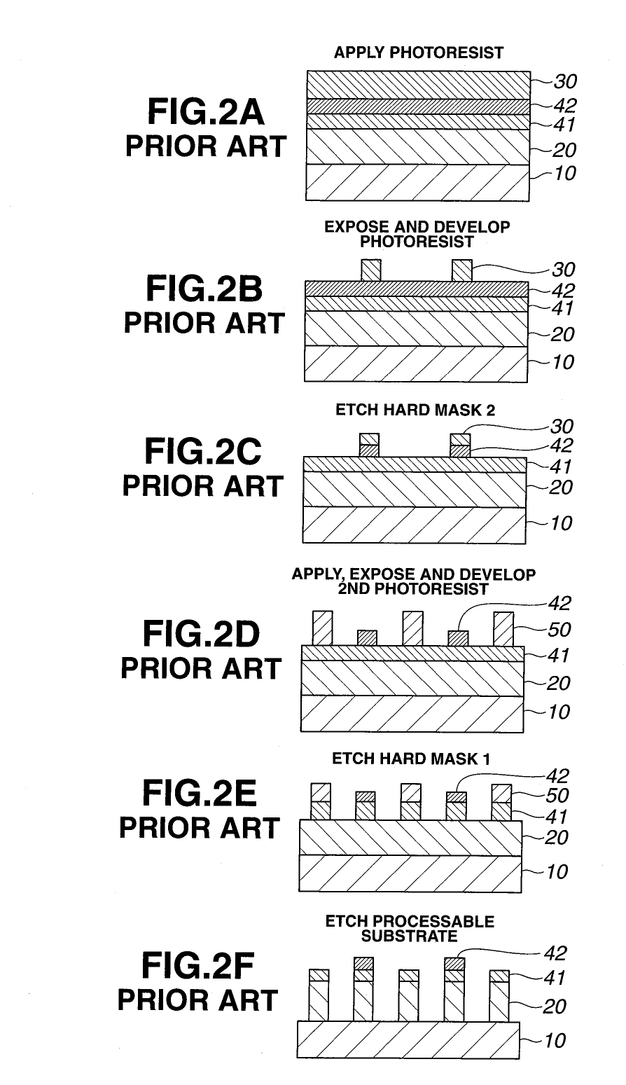

To solve the above problem, a double patterning process 2 illustrated in FIG. 2 involves laying two layers of hard mask 41 and 42. The upper layer of hard mask 42 is processed using a first resist pattern, the lower layer of hard mask 41 is processed using a second resist pattern, and the processable substrate is dry etched using the two hard mask patterns. It is essential to establish a high etching selectivity between first hard mask 41 and second hard mask 42. Thus the process is rather complex.

FIG. 2-A shows a laminate of substrate 10, processable substrate 20, 1st and 2nd hard masks 41 and 42, and resist film 30, FIG. 2-B shows resist film 30 being exposed and developed, FIG. 2-C shows 2nd hard mask 42 being etched, FIG. 2-D shows, after removal of first resist film 30, a second resist film 50 being formed, exposed and developed, FIG. 2-E shows 1st hard mask 41 being etched, and FIG. 2-F shows processable substrate 20 being etched.

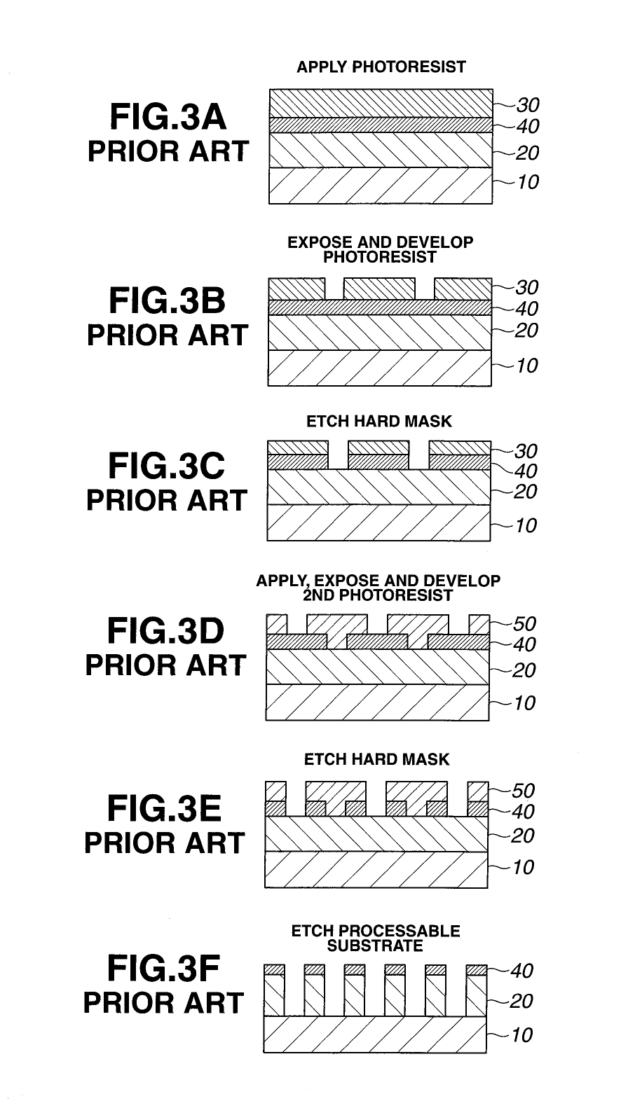

FIG. 3 illustrates a double patterning process 3 using a trench pattern. This process requires only one layer of hard mask. However, since the trench pattern is lower in optical contrast than the line pattern, the process has the drawbacks of difficult resolution of the pattern after development and a narrow margin. It is possible to form a wide trench pattern and induce shrinkage by the thermal flow or RELACS method, but this process is more intricate. Using negative resist materials enables exposure at a high optical contrast, but the negative resist materials generally have the drawbacks of low contrast and low resolution capability as compared with positive resist materials. The trench process requires a very high accuracy of alignment because any misalignment between the first and second trenches leads to a variation in the width of the finally remaining lines.

FIG. 3-A shows a laminate of substrate 10, processable substrate 20, hard mask 40, and resist film 30, FIG. 3-B shows resist film 30 being exposed and developed, FIG. 3-C shows hard mask 40 being etched, FIG. 3-D shows, after removal of first resist film 30, a second resist film 50 being formed, exposed and developed, FIG. 3-E shows hard mask 40 being etched, and FIG. 3-F shows processable substrate 20 being etched.

The double patterning processes 1 to 3 described above have the drawback that two hard mask etchings are involved.

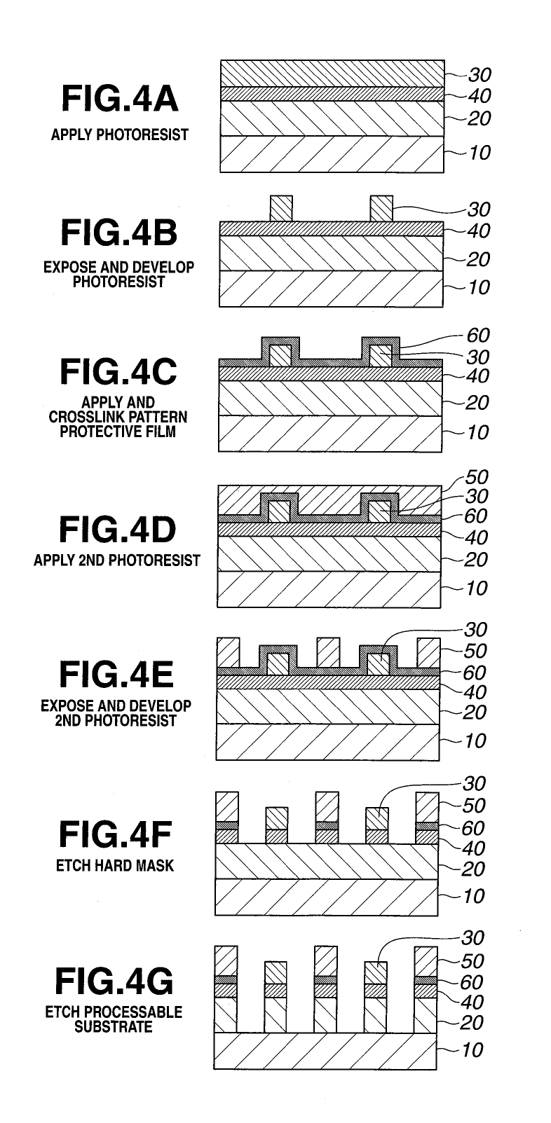

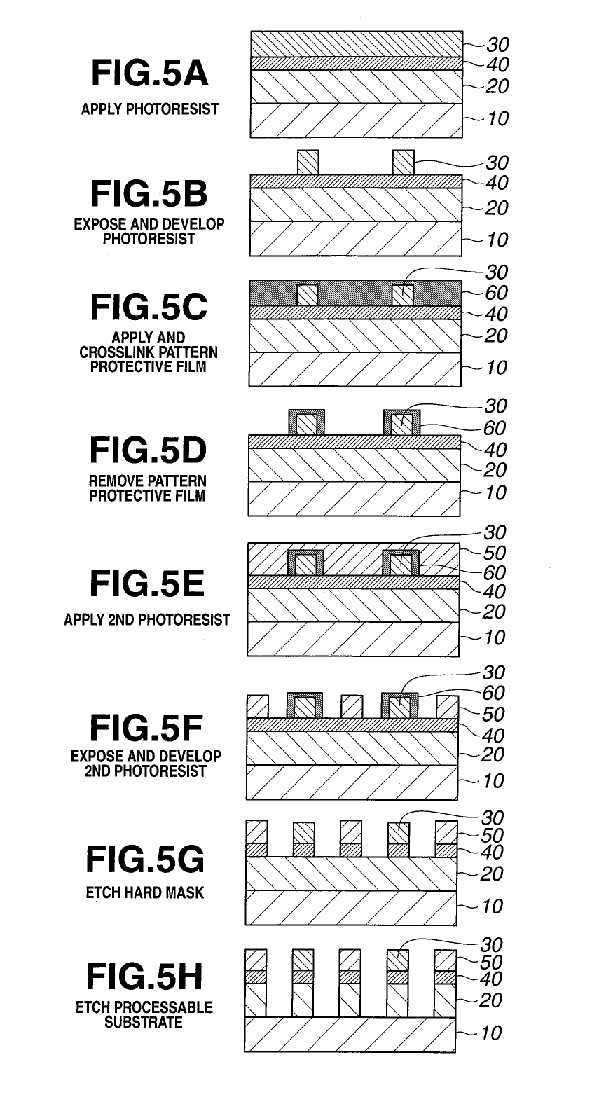

FIGS. 4 and 5 illustrate double patterning processes according to claim 1 and claims 2, 3 of the invention, respectively.

FIG. 4-A shows a structure wherein a hard mask 40 and a first resist film 30 are formed on a processable substrate 20 on a substrate 10, FIG. 4-B shows first resist film 30 being exposed and developed, FIG. 4-C shows a pattern protective coating material 60 being coated and crosslinked on first resist pattern 30, FIG. 4-D shows a second positive resist material 50 being coated, FIG. 4-E shows a second resist pattern 50 being formed, FIG. 4-F shows extra crosslinked film 60 and hard mask 40 being etched away, and FIG. 4-G shows processable substrate 20 being etched.

FIG. 5-A shows a structure wherein a hard mask 40 and a first resist film 30 are formed on a processable substrate 20 on a substrate 10, FIG. 5-B shows first resist film 30 being exposed and developed, FIG. 5-C shows a pattern protective coating material 60 being coated and crosslinked on first resist pattern 30, FIG. 5-D shows extra protective film 60 being removed, FIG. 5-E shows a second positive resist material 50 being coated, FIG. 5-F shows a second resist pattern 50 being formed, FIG. 5-G shows extra crosslinked film 60 and hard mask 40 being etched away, and FIG. 5-H shows processable substrate 20 being etched.

In the patterning process, a resist pattern protective coating material comprising a silicon compound having at least one amino group and a hydrolysis reactive group is coated on a first resist pattern and baked. Baking is effected at a temperature of 50 to 200° C. for 3 to 300 seconds.

In the patterning process according to claims 2 and 3, the extra silicon compound is then stripped off using water, developer, solvent or a mixture thereof. The patterning process according to claim 1 omits such stripping. In an embodiment wherein the substrate on which the first resist pattern is formed is a silicon-containing antireflective coating, no problems arise when the stripping step is omitted. If residual amino groups on the substrate can cause a footing profile to the second resist pattern, or if the substrate used is an organic antireflective coating, it is desired to include the stripping step to remove the silicon compound having an amino group and a hydrolysis reactive group on the substrate. Where the stripping step is omitted, baking is effected at a temperature which is higher than the baking temperature employed where the stripping step is included, for example, of 100 to 200° C., and preferably 120 to 200° C. because a robust resist pattern protective film must be formed. Where the stripping step is included, baking of the resist pattern protective film is intended for evaporation of the solvent and adsorption of amino groups on the resist film, and in this sense, baking at a low temperature of 50 to 150° C. is satisfactory. After the silicon compound is stripped off using water, developer and/or solvent, baking may be effected between the steps of FIGS. 5-D and 5-E. This baking serves to accelerate hydrolytic condensation of alkoxysilane to form a robust resist pattern protective film.

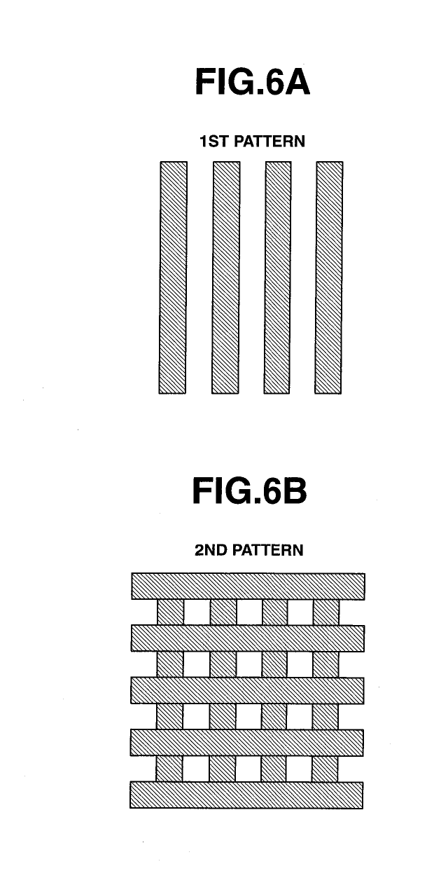

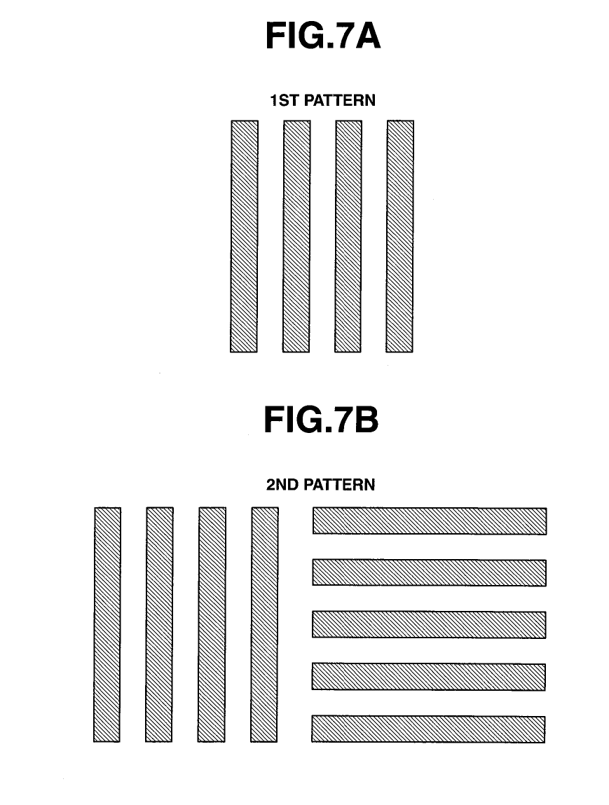

Although the process illustrated in FIGS. 4 and 5 forms the second pattern between lines of the first pattern, it is also acceptable to form the second pattern so as to cross the first pattern orthogonally as shown in FIG. 6. Although such a pattern may be formed through a single exposure step, an orthogonal line pattern may be formed at a very high contrast by a combination of dipolar illumination with polarized illumination. Specifically, pattern lines in Y direction are formed as shown in FIG. 6-A and then protected from dissolution by the process of the invention. Thereafter, a second resist is coated and processed to form pattern lines in X direction as shown in FIG. 6-B. Combining X and Y lines defines a grid pattern while empty areas become holes. The pattern that can be formed by such a process is not limited to the orthogonal pattern, and may include a T-shaped pattern (not shown) or a separated pattern as shown in FIG. 7.

The substrate 10 used herein is generally a silicon substrate. The processable substrate 20 used herein includes SiO₂, SiN, SiON, SiOC, p-Si, α-Si, TiN, WSi, BPSG, SOG, Cr, CrO, CrON, MoSi, low dielectric film, and etch stopper film. The hard mask 40 is as described above. Notably a bottom layer in the form of a carbon film or an intermediate intervening layer such as a silicon-containing intermediate film or an organic antireflective coating may be formed in stead of the hard mask.

In the process of the invention, a first resist film 30 of first positive resist material is formed on the processable substrate directly or via the intermediate intervening layer. The first resist film preferably has a thickness of 10 to 1,000 nm, and more preferably 20 to 500 nm. The resist film is heated or pre-baked prior to exposure, with the preferred pre-baking conditions including a temperature of 60 to 180° C., especially 70 to 150° C. and a time of 10 to 300 seconds, especially 15 to 200 seconds.

This is followed by exposure. For the exposure, preference is given to high-energy radiation having a wavelength of 140 to 250 nm, and especially ArF excimer laser radiation of 193 nm. The exposure may be done either in air or in a dry atmosphere with a nitrogen stream, or by immersion lithography in water. The ArF immersion lithography uses pure water or liquids having a refractive index of at least 1 and highly transparent to the exposure wavelength such as alkanes as the immersion solvent. The immersion lithography involves prebaking a resist film and exposing the resist film to light through a projection lens, with water (or liquid) introduced between the resist film and the projection lens. Since this allows lenses to be designed to a NA of 1.0 or higher, formation of finer feature size patterns becomes possible. The immersion lithography is important for the ArF lithography to survive to the 45-nm node. In the case of immersion lithography, pure water rinsing (or post-soaking) may be carried out after exposure for removing water droplets left on the resist film, or a protective coating may be applied onto the resist film after pre-baking for preventing any leach-out from the resist film and improving water slip on the film surface. The resist protective coating used in the immersion lithography is preferably formed from a solution of a polymer having 1,1,1,3,3,3-hexafluoro-2-propanol residues which is insoluble in water, but soluble in an alkaline developer liquid, in a solvent selected from alcohols of at least 4 carbon atoms, ethers of 8 to 12 carbon atoms, and mixtures thereof. After formation of the photoresist film, pure water rinsing (or post-soaking) may be carried out for extracting the acid generator and the like from the film surface or washing away particles, or after exposure, rinsing (or post-soaking) may be carried out for removing water droplets left on the resist film.

Exposure is preferably carried out so as to provide an exposure dose of about 1 to 200 mJ/cm², more preferably about 10 to 100 mJ/cm². This is followed by baking on a hot plate at 60 to 150° C. for 1 to 5 minutes, preferably at 80 to 120° C. for 1 to 3 minutes (post-exposure baking=PEB). Thereafter the resist film is developed with a developer in the form of an aqueous alkaline solution, for example, an aqueous solution of 0.1 to 5 wt %, preferably 2 to 3 wt % tetramethylammonium hydroxide (TMAH) for 0.1 to 3 minutes, preferably 0.5 to 2 minutes by conventional techniques such as dip, puddle or spray techniques. In this way, a desired resist pattern is formed on the substrate.

In the double patterning process of forming a second resist pattern in spaces of a first resist pattern, the distance between pattern features is substantially reduced, with an increased likelihood that pattern features after development collapse down. It is believed that the pattern collapse is caused by stresses produced during drying of rinse liquid after development. Means known effective for preventing such pattern collapse include (1) reducing the aspect ratio of pattern (reducing the resist film thickness or increasing the line size), (2) increasing the space distance, (3) reducing the surface energy of resist, and (4) reducing the surface energy of rinse liquid. Since the line width and resist film thickness are generally not variable, it is effective to use pure water containing a surfactant with a low surface tension as the rinse liquid instead of water having a high surface energy level. It is also necessary that the resist surface after development be of lower energy. The energy of the resist surface may be represented by a contact angle with water. A contact angle is commonly measured by a liquid droplet method. A water droplet of 1 to 20 μL is dispensed on a resist surface and an angle at the interface between the resist and the droplet is measured. Standard ArF resists have a contact angle with water of 55° to 70°. A higher contact angle with water is more effective for preventing pattern collapse. The preferred contact angle is at least 50°, more preferably at least 60°. This is true for the contact angle of the resist surface when a pattern protective film is applied to the resist surface according to the invention.

To cure the resist pattern after development, crosslinking may be induced by irradiating light with wavelength up to 200 nm and optionally heating, prior to or subsequent to coating of the pattern protective film. Light irradiation after development preferably utilizes high-energy radiation with wavelength up to 200 nm, for example, ArF excimer radiation of 193 nm wavelength, Xe₂ excimer radiation of 172 nm wavelength, F₂ excimer radiation of 157 nm wavelength, Kr₂ excimer radiation of 146 nm wavelength, and Ar₂ excimer radiation of 126 nm wavelength. In the case of radiation, the exposure dose is in the range of 10 mJ/cm² to 10 J/cm². Irradiation of radiation with wavelength up to 200 nm, for example, an excimer laser of 193 nm, 172 nm, 157 nm, 146 nm or 122 nm wavelength, or an excimer lamp not only causes the photoacid generator to generate an acid, but also promotes photo-induced crosslinking reaction.

In an embodiment wherein a thermal acid generator such as an ammonium salt has been added to the photoresist material in an amount of 0.001 to 20 parts, preferably 0.01 to 10 parts by weight per 100 parts by weight of the base resin, the acid may be generated by heating. In this embodiment, acid generation and crosslinking reaction take place simultaneously. Preferred heating conditions include a temperature of 100 to 300° C., especially 130 to 250° C. and a time of 10 to 500 seconds. This ensures that a crosslinked resist layer which is insoluble in solvent and alkaline developer is formed on the resist film surface at the time when a resist protective coating material is coated and baked.

By coating and baking an amino-containing silane compound according to the invention, the line width roughness (LWR) can be reduced. To improve the LWR which is required to be minimized with the reducing pattern size, attempts have been made for reducing LWR by heat treatment or solvent treatment. The line edge portions which are reduced so that the line width is concave are those portions of continuing dissolution and hence, having a higher proportion of carboxyl groups. Since the amino-containing silane compound according to the invention adsorbs to carboxyl groups, more silane compound adsorbs to the concave line portions, which is effective in improving LWR.

The LWR of a line pattern may also be reduced by coating a pattern protective film according to the invention. Reduction of LWR is the important goal in the lithography technology. Methods of reducing LWR by heating a pattern to provide a thermal flow, by etching, and by a combination of DUV cure and solvent treatment are described in Proc. SPIE Vol. 6923 p 69231E1 (2008).

The thermal acid generator in the form of an ammonium salt includes those of the following formula.

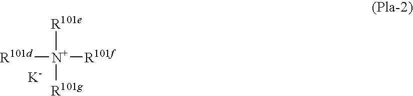

Herein R^{101d}, R^{101e}, R^{101f}, and R^{101g} each independently stand for hydrogen, a straight, branched or cyclic C₁-C₁₂ alkyl, alkenyl, oxoalkyl or oxoalkenyl group, C₆-C₂₀ aryl group, or C₇-C₁₂ aralkyl or aryloxoalkyl group wherein some or all hydrogen atoms may be replaced by alkoxy groups. A pair of R^{101d} and R^{101e} or a combination of R^{101d}, R^{101e} and R^{101f} may form a ring, and each of R^{101d} and R^{101e} or each of R^{101d}, R^{101e} and R^{101f} is a C₃-C₁₀ alkylene group or a hetero-aromatic ring having the nitrogen atom (in the formula) incorporated therein, when they form a ring. K⁻ is a sulfonate which is fluorinated at one or more α-positions, perfluoroalkylimidate or perfluoroalkylmethidate.

Examples of K⁻ include perfluoroalkanesulfonates such as triflate and nonaflate; imidates such as bis(trifluoromethylsulfonyl)imide, bis(perfluoroethylsulfonyl)imide, and bis(perfluorobutylsulfonyl)imide; methidates such as tris(trifluoromethylsulfonyl)methide and tris(perfluoroethylsulfonyl)methide; sulfonates having fluorine substituted at α-position as represented by the general formula (K-1) and sulfonates having fluorine substituted at α-position as represented by the general formula (K-2).

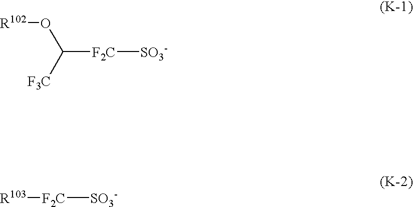

In formula (K-1), R¹⁰² is hydrogen, or a straight, branched or cyclic C₁-C₂₀ alkyl or acyl group, C₂-C₂₀ alkenyl group, or C₆-C₂₀ aryl or aryloxy group, which may have an ether group, ester group, carbonyl group or lactone ring, or in which some or all hydrogen atoms may be substituted by fluorine atoms. In formula (K-2), R¹⁰³ is hydrogen, or a straight, branched or cyclic C₁-C₂₀ alkyl group, C₂-C₂₀ alkenyl group, or C₆-C₂₀ aryl group.

If light of wavelength below 180 nm is irradiated in air, ozone forms, with which the resist surface is oxidized, leading to a substantial loss of film thickness. Since ozone oxidation by light irradiation is generally utilized for cleaning off the organic deposits on substrates, the resist film is also cleaned by ozone, with the risk that the film can be extinguished if the exposure dose is substantial. Thus, where an excimer laser of wavelength 172 nm, 157 nm, 146 nm or 122 nm, or an excimer lamp is used, it is recommended to purge the chamber with an inert gas such as nitrogen, He, Ar, or Kr gas, so that light may be irradiated in an atmosphere having an oxygen or moisture concentration of up to 10 ppm.

Next, a second resist material is coated on the intermediate intervening layer (e.g., hard mask) having the pattern of crosslinked resist film thereon, to form a second resist film. Preferably the second resist material is a positive resist material, more preferably positive chemically amplified resist material. As the second resist material, any well-known resist materials may be used as well as the above-described first resist material. The pattern forming process of the invention is characterized in that development of the first resist pattern is followed by crosslinking reaction, whereas development of the second resist pattern need not be followed by crosslinking reaction. Namely, for the resist material for forming the second resist pattern, naphthol units are not essential, and any well-known chemically amplified positive resist materials may be used.

Preferably the second resist film is exposed and developed in a conventional way to form a pattern of second resist film in the space area of the pattern of crosslinked resist film, for thereby reducing the distance between patterns to one half. The thickness of and the exposure and development conditions of the second resist film may be the same as the previous conditions.

Next, using the first (crosslinked) resist film and second resist film as a mask, the intermediate intervening layer (e.g., hard mask) is etched, and the processable substrate further etched. For etching of the intermediate intervening layer such as hard mask, dry etching with fluorocarbon or halogen gases may be used. For etching of the processable substrate, the etching gas and conditions may be properly chosen so as to establish an etching selectivity relative to the hard mask, and specifically, dry etching with fluorocarbon, halogen, oxygen, hydrogen or similar gases may be used. Thereafter, the first (crosslinked) resist film and second resist film are removed. Removal of these films may be carried out after etching of the intermediate intervening layer such as hard mask. It is noted that removal of the crosslinked resist film may be achieved by dry etching with oxygen or radicals and removal of the second resist film may be achieved as previously described, or using strippers such as amines, sulfuric acid/aqueous hydrogen peroxide in organic solvents.

### Example

Examples of the invention are given below by way of illustration and not by way of limitation. The abbreviations used herein are GPC for gel permeation chromatography, Mw for weight average molecular weight, Mn for number average molecular weight, and Mw/Mn for molecular weight distribution or polydispersity index, and TMAH for tetramethylammonium hydroxide. For all polymers, Mw and Mn are determined by GPC versus polystyrene standards.

### Preparation of Protective Coating Material

A resist pattern protective coating solution was prepared by mixing a silicon compound and a solvent in accordance with the recipe shown in Table 1 and filtering through a Teflon® filter with a pore size of 0.2 μm. Note that polyvinyl pyrrolidone having Mw=10,000 and Mw/Mn=1.92 is commercially available from Aldrich.

TABLE 1

| | Silicon compound (pbw) | Organic solvent (pbw) |
|---|---|---|
| Pattern protective | | |
| coating material | | |
| 1 | 3-(aminoethylaminopropyl)trimethoxysilane (10) | isobutyl alcohol (10,000) |
| | | water (500) |
| 2 | 3-(aminoethylaminopropyl)triethoxysilane (10) | isobutyl alcohol (1,000) |
| | | water (50) |
| 3 | 3-aminopropyltriethoxysilane (10) | isobutyl alcohol (1,000) |
| | | water (50) |
| 4 | 3-(2-aminoethylaminopropyl)dimethoxymethylsilane (10) | isobutyl alcohol (1,000) |
| | | water (50) |
| 5 | 2-(2-aminoethylthioethyl)trimethoxysilane (10) | isobutyl alcohol (1,000) |
| | | water (50) |
| 6 | 3-[2-(2-aminoethylaminoethylamino)propyl]trimethoxy- | isobutyl alcohol (1,000) |
| | silane (10) | water (50) |
| 7 | 3-morpholinopropyltrimethoxysilane (10) | isobutyl alcohol (1,000) |
| | | water (50) |
| 8 | 3-piperazinopropyltrimethoxysilane (10) | isobutyl alcohol (1,000) |
| | | water (50) |
| 9 | 3-(glycidylpropyl)trimethoxysilane (10) | isobutyl alcohol (1,000) |
| | N-hydroxyethylethylenediamine (5) | water (50) |
| 10 | 3-(aminoethylaminopropyl)trimethoxysilane (10) | 4-methyl-2-pentanol (1,000) |
| | | water (50) |
| 11 | 3-(aminoethylaminopropyl)trimethoxysilane (8) | 4-methyl-2-pentanol (1,000) |
| | methyltrimethoxysilane (2) | water (50) |
| 12 | 3-(aminoethylaminopropyl)trimethoxysilane (8) | 4-methyl-2-pentanol (1,000) |
| | phenyltrimethoxysilane (2) | water (50) |
| 13 | 3-(aminoethylaminopropyl)trimethoxysilane (8) | 4-methyl-2-pentanol (1,000) |
| | methyltriethoxysilane (2) | water (50) |
| 14 | 3-(aminoethylaminopropyl)trimethoxysilane (8) | 4-methyl-2-pentanol (1,000) |
| | phenyltriethoxysilane (2) | water (50) |
| 15 | 3-(aminoethylaminopropyl)trimethoxysilane (8) | 4-methyl-2-pentanol (1,000) |
| | methyltri-n-propoxysilane (2) | water (50) |
| 16 | 3-(aminoethylaminopropyl)trimethoxysilane (8) | 4-methyl-2-pentanol (1,000) |
| | cyclohexyltriethoxysilane (2) | water (50) |
| 17 | 3-(aminoethylaminopropyl)trimethoxysilane (8) | 4-methyl-2-pentanol (1,000) |
| | methyl-methoxy/ethoxy/propoxy mixed trialkoxysilane (2) | water (50) |
| 18 | 3-(aminoethylaminopropyl)trimethoxysilane (10) | isobutyl alcohol (10, 000) |
| | titanium diisopropoxybis(triethanolaminate) (2) | water (50) |
| 19 | N-3-(triethoxysilyl)propyl-N,N,N-trimethylammonium | isobutyl alcohol (10, 000) |
| | hydroxide (10) | water (50) |
| 20 | 3-(aminoethylaminopropyl)triethoxysilane (10) | isobutyl alcohol (1,000) |
| | 3-(2-aminoethylaminopropyl)dimethoxymethylsilane (2) | water (50) |
| 21 | 3-(aminoethylaminopropyl)triethoxysilane (10) | isobutyl alcohol (1,000) |
| | 3-(2-aminoethylaminopropyl)dimethoxymethylsilane (2) | water (50) |
| | polyvinyl pyrrolidone (10) | |
| 22 | 3-(2-aminoethylaminopropyl)dimethoxymethylsilane (5) | 4-methyl-2-pentanol (1,000) |
| | 3,3,3-trifluoropropyltrimethoxysilane (1) | water (50) |
| 23 | 3-(2-aminoethylaminopropyl)dimethoxymethylsilane (5) | 4-methyl-2-pentanol (1,000) |
| | 3,3,4,4,5,5,6,6,6-nonafluorohexyltrimethoxysilane (1) | water (50) |
| 24 | 3-(2-aminoethylaminopropyl)dimethoxymethylsilane (5) | 4-methyl-2-pentanol (1,000) |
| | heptyltrimethoxysilane (1) | water (50) |
| Comparative | | |
| Pattern | | |
| protective | | |
| coating | | |
| material | | |
| 1 | 3-(glycidylpropyl)trimethoxysilane (10) | isobutyl alcohol (1,000) |
| | | water (50) |
| 2 | allyltrimethoxysilane (10) | isobutyl alcohol (1,000) |
| | | water (50) |
| 3 | 3-(mercaptopropyl)trimethoxysilane (10) | isobutyl alcohol (1,000) |
| | | water (50) |
| 4 | methyltrimethoxysilane (10) | isobutyl alcohol (1,000) |
| | | water (50) |
| 5 | phenyltrimethoxysilane (10) | isobutyl alcohol (1,000) |
| | | water (50) |

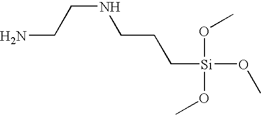

3-(2-Aminoethylaminopropyl)trimethoxysilane

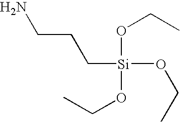

3-Aminopropyltriethoxysilane

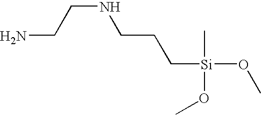

3-(2-Aminoethylaminopropyl)dimethoxymethylsilane

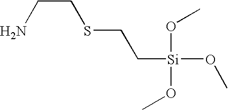

2-(2-Aminoethythioethyl)trimethoxysilane

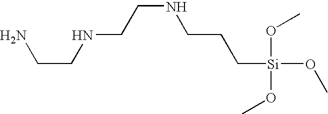

3-[2-(2-Aminoethylaminoethylamino)propyl]trimethoxysilane

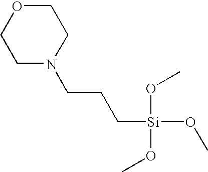

3-Morpholinopropyltrimethoxysilane

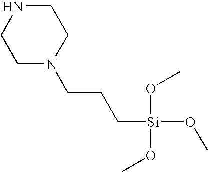

3-Piperazinopropyltrimethoxysilane

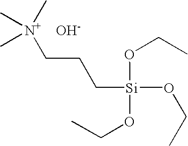

N-3-(Triethoxysilyl)propyl-N,N,N-trimethylammoniumhydroxide

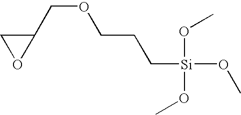

3-Glycidoxypropyltrimethoxysilane

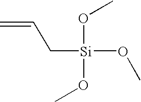

Allyltrimethoxysilane

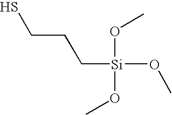

3-Mercaptopropyltrimethoxysilane

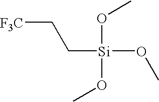

3,3,3-Trifluoropropyltrimethoxysilane

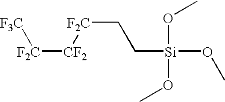

3,3,4,4,5,5,6,6,6-Nonafluorohexyltrimethoxysilane

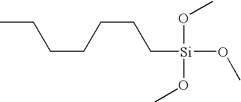

Heptyltrimethoxysilane

### Synthesis Example

As the base resin to be added to resist materials, polymers of the following construction (Resist Polymers 1 to 10) were synthesized by combining particular monomers, followed by copolymerization reaction in tetrahydrofuran, crystallization in methanol, repeated washing with hexane, isolation, and drying. The construction of the polymer was identified by ¹H-NMR, and the molecular weight (Mw) and polydispersity index (Mw/Mn) thereof were determined by GPC.

### Resist Polymer 1 Mw=8,100

Mw/Mn=1.75

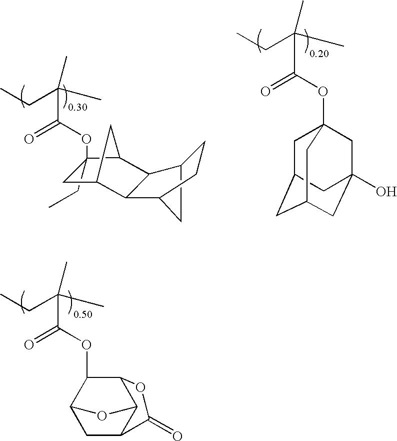

### Resist Polymer 2 Mw=8,800

Mw/Mn=1.77

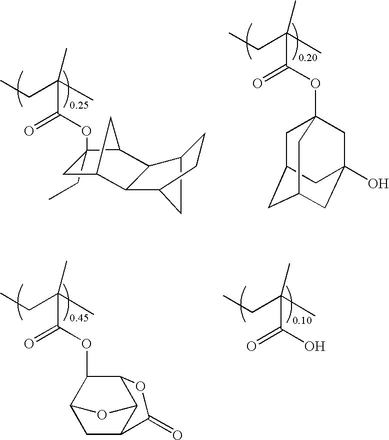

### Resist Polymer 3 Mw=7,600

Mw/Mn=1.80

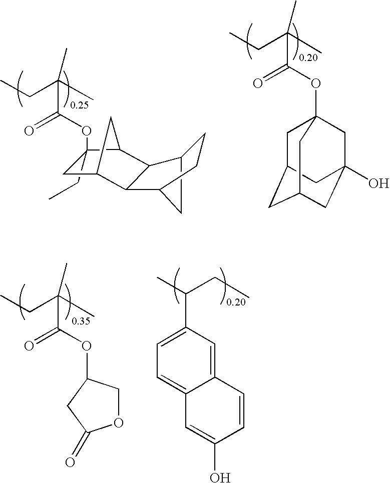

### Resist Polymer 4 Mw=9,100

Mw/Mn=1.72

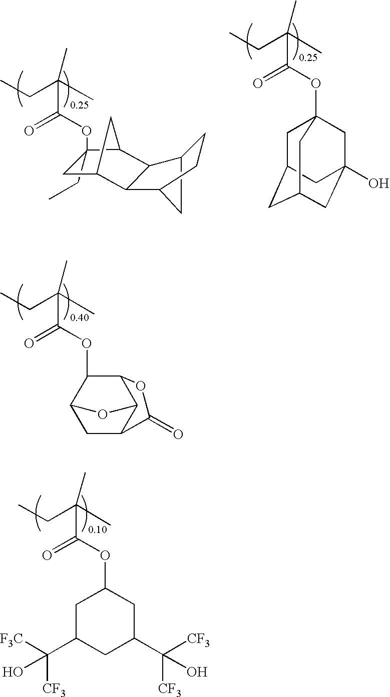

### Resist Polymer 5 Mw=7,800

Mw/Mn=1.79

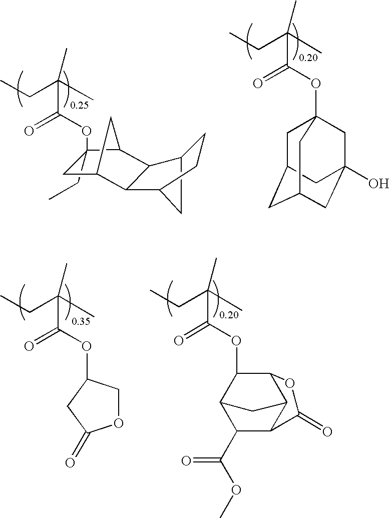

### Resist Polymer 6 Mw=7,600

Mw/Mn=1.79

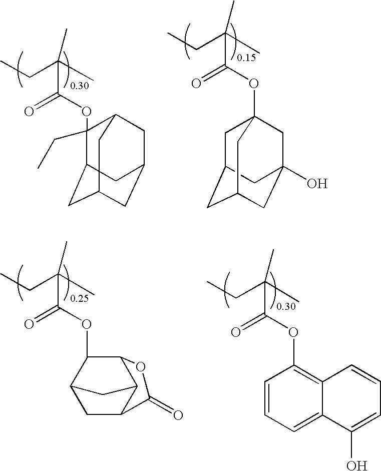

### Resist Polymer 7 Mw=8,200

Mw/Mn=1.71

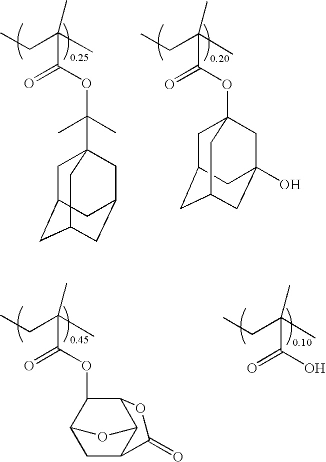

### Resist Polymer 8 Mw=8,600

Mw/Mn=1.83

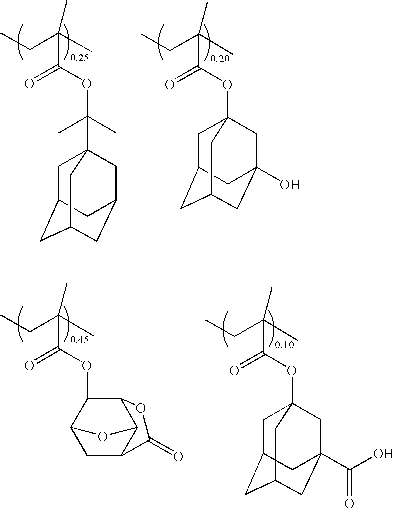

### Resist Polymer 9 Mw=8,300

Mw/Mn=1.96

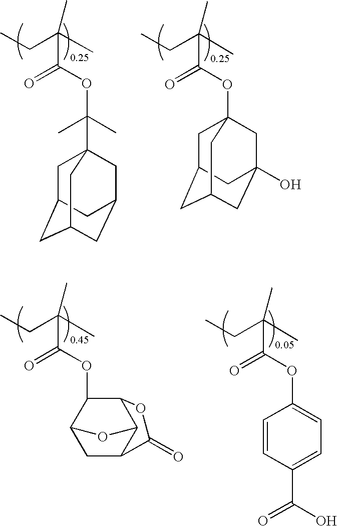

### Resist Polymer 10 Mw=8,400

Mw/Mn=1.99

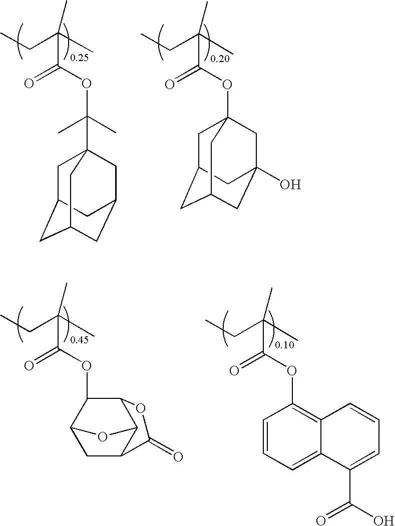

### Preparation of Resist Solution

A resist solution was prepared by dissolving each of the above-synthesized polymers (Resist Polymers 1 to 10), acid generator, and basic compound in a solvent in accordance with the recipe shown in Table 2, and filtering through a Teflon® filter with a pore size of 0.2 μm.

The components in Table 2 are identified below.
Acid generators: Photoacid generator PAG1 of the following structural formula
   Thermal acid generator TAG1 of the following structural formula
Basic compound: Quencher 1 of the following structural formula

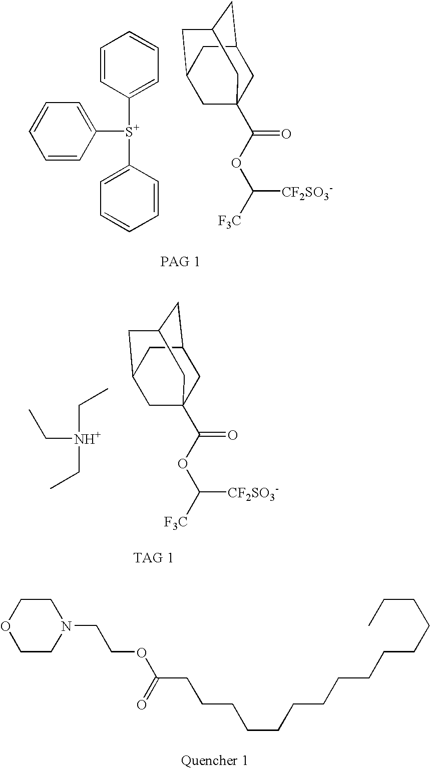

Organic solvents:propylene glycol monomethyl ether acetate (PGMEA)
   cyclohexanone (CyH)

TABLE 2

| Resist | | Acid | Basic | Organic |
|---|---|---|---|---|
| material | Polymer (pbw) | generator (pbw) | compound (pbw) | solvent (pbw) |
| Resist 1 | Resist Polymer 1 (100) | PAG1 (14.0) | Quencher1 (1.60) | PGMEA (2,000) |
| | | | | CyH (500) |
| Resist 2 | Resist Polymer 2 (100) | PAG1 (14.0) | Quencher1 (1.60) | PGMEA (2,000) |
| | | | | CyH (500) |
| Resist 3 | Resist Polymer 3 (100) | PAG1 (14.0) | Quencher1 (1.60) | PGMEA (2,000) |
| | | | | CyH (500) |
| Resist 4 | Resist Polymer 4 (100) | PAG1 (14.0) | Quencher1 (1.60) | PGMEA (2,000) |
| | | | | CyH (500) |
| Resist 5 | Resist Polymer 5 (100) | PAG1 (14.0) | Quencher1 (1.60) | PGMEA (2,000) |
| | | | | CyH (500) |
| Resist 6 | Resist Polymer 6 (100) | PAG1 (14.0) | Quencher1 (1.60) | PGMEA (2,000) |
| | | | | CyH (500) |
| Resist 7 | Resist Polymer 4 (100) | PAG1 (14.0) | Quencher1 (1.60) | PGMEA (2,000) |
| | | TAG1 (1.0) | | CyH (500) |
| Resist 8 | Resist Polymer 7 (100) | PAG1 (14.0) | Quencher1 (1.60) | PGMEA (2,000) |
| | | | | CyH (500) |
| Resist 9 | Resist Polymer 8 (100) | PAG1 (14.0) | Quencher1 (1.60) | PGMEA (2,000) |
| | | | | CyH (500) |
| Resist 10 | Resist Polymer 9 (100) | PAG1 (14.0) | Quencher1 (1.60) | PGMEA (2,000) |
| | | | | CyH (500) |
| Resist 11 | Resist Polymer 10 (100) | PAG1 (14.0) | Quencher1 (1.60) | PGMEA (2,000) |
| | | | | CyH (500) |

### Preparation of Topcoat Solution

Topcoat Polymer
Mw=8,800
Mw/Mn=1.69

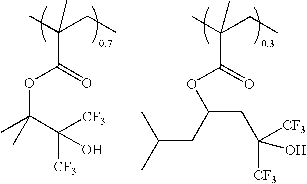

A topcoat solution was prepared by mixing a polymer (Topcoat Polymer) with a solvent in accordance with the recipe of Table 3 and filtering through a Teflon® filter with a pore size of 0.2 μm.

TABLE 3

| Topcoat solution | Polymer (pbw) | Organic solvent (pbw) |
|---|---|---|
| TC1 | Topcoat Polymer (100) | diisoamyl ether (2,700) |
| | | 2-methyl-1-butanol (270) |

### Examples and Comparative Examples

### Pattern Curing Test

The pattern protective coating material shown in Table 1 was coated onto a silicon wafer and baked at 100° C. for 60 seconds to form a protective film. The film thickness was measured by a spectrometric film thickness measurement system (Lambda Ace by Dainippon Screen Co., Ltd.).

Next, on a substrate (silicon wafer) having deposited thereon an antireflective coating (ARC-29A, Nissan Chemical Industries, Ltd.) of 80 nm thick, the resist material shown in Table 2 was spin coated and baked on a hot plate at 110° C. for 60 seconds to form a resist film of 100 nm thick.

The resist film was exposed by means of an ArF excimer laser scanner model NSR-S307E (Nikon Corp., NA 0.85, σ 0.93/0.62, 20° dipole illumination, 6% halftone phase shift mask). Immediately after exposure, the resist film was baked at 100° C. for 60 seconds and then developed for 30 seconds with a 2.38 wt % TMAH aqueous solution, obtaining a positive resist pattern consisting of lines of 65 nm size at a pitch of 130 nm.

Next, in Examples 1 to 37 and Comparative Examples 2 to 6, the pattern protective coating material was coated onto the resist pattern and baked and in some cases, rinsed with pure water at 2,000 rpm for 20 seconds to remove the extra protective coating material. In the case of removal with a developer, puddle development was carried out for 30 seconds, followed by pure water rinsing. Thereafter, in some cases, the resist pattern was insolubilized by baking. The following two tests were carried out to examine whether the resist pattern was insolubilized.

PGMEA was dispensed on the resist pattern for 20 seconds, after which the pattern-bearing wafer was spun at 2,000 rpm for 20 seconds and baked at 100° C. for 60 seconds to evaporate off PGMEA. Then the pattern-bearing wafer was subjected to flood expossure (over its entire surface) by the ArF excimer laser scanner in an exposure dose of 50 mJ/cm², baked at 100° C. for 60 seconds, and developed for 30 seconds with a 2.38 wt % TMAH aqueous solution. Using a measuring SEM model S-9380 (Hitachi Hitechnologies), the pattern size was measured both after the PGMEA treatment and after the development. In Comparative Example 1, the pattern protective coating material was not applied.

The results are shown in Table 4.

TABLE 4

| | | | | Pattern | Baking conditions | | Baking | | |
|---|---|---|---|---|---|---|---|---|---|
| | | | | protective | after coating of | | conditions | Pattern size | Pattern size |
| | | Resist | Pattern protective | film thickness | pattern protective | Rinse | after | after PGMEA | after flood |
| | | material | coating material | (nm) | coating material | liquid | rinsing | treatment | exposure |
| Example | 1 | Resist 1 | Pattern protective | 2 | 160° C./60 sec | — | — | 70 | 69 |
| | | | coating material 1 | | | | | | |
| | 2 | Resist 1 | Pattern protective | 50 | 100° C./60 sec | water | 160° C./60 sec | 66 | 65 |
| | | | coating material 2 | | | | | | |
| | 3 | Resist 1 | Pattern protective | 50 | 100° C./60 sec | water | 160° C./60 sec | 65 | 65 |
| | | | coating material 3 | | | | | | |
| | 4 | Resist 1 | Pattern protective | 50 | 100° C./60 sec | water | 160° C./60 sec | 65 | 65 |
| | | | coating material 4 | | | | | | |
| | 5 | Resist 1 | Pattern protective | 50 | 100° C./60 sec | water | 160° C./60 sec | 65 | 65 |
| | | | coating material 5 | | | | | | |
| | 6 | Resist 1 | Pattern protective | 50 | 100° C./60 sec | water | 160° C./60 sec | 65 | 65 |
| | | | coating material 6 | | | | | | |
| | 7 | Resist 1 | Pattern protective | 50 | 100° C./60 sec | water | 160° C./60 sec | 65 | 65 |
| | | | coating material 7 | | | | | | |
| | 8 | Resist 1 | Pattern protective | 50 | 100° C./60 sec | water | 160° C./60 sec | 65 | 65 |
| | | | coating material 8 | | | | | | |
| | 9 | Resist 1 | Pattern protective | 50 | 100° C./60 sec | water | 160° C./60 sec | 65 | 64 |
| | | | coating material 9 | | | | | | |
| | 10 | Resist 1 | Pattern protective | 50 | 100° C./60 sec | water | 160° C./60 sec | 65 | 64 |
| | | | coating material 10 | | | | | | |
| | 11 | Resist 1 | Pattern protective | 50 | 100° C./60 sec | water | 160° C./60 sec | 68 | 68 |
| | | | coating material 11 | | | | | | |
| | 12 | Resist 1 | Pattern protective | 50 | 100° C./60 sec | water | 160° C./60 sec | 71 | 70 |
| | | | coating material 12 | | | | | | |
| | 13 | Resist 1 | Pattern protective | 50 | 100° C./60 sec | water | 160° C./60 sec | 66 | 63 |
| | | | coating material 2 | | | | | | |
| | 14 | Resist 2 | Pattern protective | 50 | 100° C./60 sec | water | 160° C./60 sec | 64 | 62 |
| | | | coating material 2 | | | | | | |
| | 15 | Resist 3 | Pattern protective | 50 | 100° C./60 sec | water | 160° C./60 sec | 66 | 65 |
| | | | coating material 2 | | | | | | |
| | 16 | Resist 4 | Pattern protective | 50 | 100° C./60 sec | water | 160° C./60 sec | 66 | 66 |
| | | | coating material 2 | | | | | | |
| | 17 | Resist 5 | Pattern protective | 50 | 100° C./60 sec | water | 160° C./60 sec | 65 | 64 |
| | | | coating material 2 | | | | | | |
| | 18 | Resist 6 | Pattern protective | 50 | 100° C./60 sec | water | 160° C./60 sec | 66 | 66 |
| | | | coating material 2 | | | | | | |
| | 19 | Resist 7 | Pattern protective | 50 | 100° C./60 sec | water | 160° C./60 sec | 60 | 60 |
| | | | coating material 2 | | | | | | |
| | 20 | Resist 1 | Pattern protective | 50 | 100° C./60 sec | developer | 160° C./60 sec | 63 | 61 |
| | | | coating material 2 | | | | | | |
| | 21 | Resist 1 | Pattern protective | 50 | 120° C./60 sec | water | — | 68 | 60 |
| | | | coating material 2 | | | | | | |
| | 22 | Resist 1 | Pattern protective | 50 | 100° C./60 sec | water | 160° C./60 sec | 66 | 65 |
| | | | coating material 13 | | | | | | |
| | 23 | Resist 1 | Pattern protective | 50 | 100° C./60 sec | water | 160° C./60 sec | 68 | 65 |
| | | | coating material 14 | | | | | | |
| | 24 | Resist 1 | Pattern protective | 50 | 100° C./60 sec | water | 160° C./60 sec | 64 | 65 |
| | | | coating material 15 | | | | | | |
| | 25 | Resist 1 | Pattern protective | 50 | 100° C./60 sec | water | 160° C./60 sec | 65 | 65 |
| | | | coating material 16 | | | | | | |
| | 26 | Resist 1 | Pattern protective | 50 | 100° C./60 sec | water | 160° C./60 sec | 65 | 65 |
| | | | coating material 17 | | | | | | |
| | 27 | Resist 1 | Pattern protective | 50 | 100° C./60 sec | water | 140° C./60 sec | 65 | 65 |
| | | | coating material 18 | | | | | | |
| | 28 | Resist 1 | Pattern protective | 50 | 100° C./60 sec | water | 130° C./60 sec | 65 | 65 |
| | | | coating material 19 | | | | | | |
| | 29 | Resist 1 | Pattern protective | 50 | 100° C./60 sec | water | 130° C./60 sec | 65 | 65 |
| | | | coating material 20 | | | | | | |
| | 30 | Resist 1 | Pattern protective | 50 | 100° C./60 sec | water | 130° C./60 sec | 70 | 70 |
| | | | coating material 21 | | | | | | |
| | 31 | Resist 1 | Pattern protective | 20 | 100° C./60 sec | water | 130° C./60 sec | 65 | 65 |
| | | | coating material 22 | | | | | | |
| | 32 | Resist 1 | Pattern protective | 20 | 100° C./60 sec | water | 130° C./60 sec | 68 | 68 |
| | | | coating material 23 | | | | | | |
| | 33 | Resist 1 | Pattern protective | 20 | 100° C./60 sec | water | 130° C./60 sec | 67 | 69 |
| | | | coating material 24 | | | | | | |
| | 34 | Resist 8 | Pattern protective | 50 | 100° C./60 sec | water | 160° C./60 sec | 65 | 66 |
| | | | coating material 2 | | | | | | |
| | 35 | Resist 9 | Pattern protective | 50 | 100° C./60 sec | water | 160° C./60 sec | 65 | 64 |
| | | | coating material 2 | | | | | | |
| | 36 | Resist 10 | Pattern protective | 50 | 100° C./60 sec | water | 160° C./60 sec | 66 | 66 |
| | | | coating material 2 | | | | | | |
| | 37 | Resist 11 | Pattern protective | 50 | 100° C./60 sec | water | 160° C./60 sec | 60 | 62 |
| | | | coating material 2 | | | | | | |
| Comparative | 1 | Resist 1 | — | — | — | — | — | no | no |
| Example | | | | | | | | pattern left | pattern left |
| | 2 | Resist 1 | Comparative Pattern | 50 | 100° C./60 sec | water | 130° C./60 sec | pattern | pattern |
| | | | protective coating | | | | | protective | protective |
| | | | material 1 | | | | | film cured | film cured |
| | | | | | | | | and not | and not |
| | | | | | | | | removable with | removable with |
| | | | | | | | | water; bridges | water; bridges |
| | | | | | | | | connecting | connecting |
| | | | | | | | | pattern | pattern |
| | | | | | | | | features | features |
| | 3 | Resist 1 | Comparative Pattern | 50 | 100° C./60 sec | water | 130° C./60 sec | no | no |
| | | | protective coating | | | | | pattern left | pattern left |
| | | | material 2 | | | | | | |
| | 4 | Resist 1 | Comparative Pattern | 50 | 100° C./60 sec | water | 130° C./60 sec | no | no |
| | | | protective coating | | | | | pattern left | pattern left |
| | | | material 3 | | | | | | |
| | 5 | Resist 1 | Comparative Pattern | 50 | 100° C./60 sec | water | 130° C./60 sec | no | no |
| | | | protective coating | | | | | pattern left | pattern left |
| | | | material 4 | | | | | | |
| | 6 | Resist 1 | Comparative Pattern | 50 | 100° C./60 sec | water | 130° C./60 sec | no | no |
| | | | protective coating | | | | | pattern left | pattern left |
| | | | material 5 | | | | | | |

In Examples 2, 23, 24 and 25 and Comparative Example 1 (not using pattern protective coating material), a contact angle with water of the resist surface was determined after rinsing and baking. The results are shown in Table 5.

TABLE 5

| | Contact angle (°) |
|---|---|
| Example 2 | 40 |
| Example 23 | 48 |
| Example 24 | 52 |
| Example 25 | 68 |
| Comparative Example 1 | 58 |

### Double Patterning Test I

On a substrate (silicon wafer) having an antireflective coating (ARC-29A, Nissan Chemical Industries, Ltd.) of 80 nm thick, resist material 1 of the composition shown in Table 2 was spin coated, then baked on a hot plate at 100° C. for 60 seconds to form a resist film of 100 nm thick. Topcoat material TC1 of the composition shown in Table 3 was coated thereon and baked at 90° C. for 60 seconds to form a topcoat film of 50 nm thick.

By immersion lithography using an ArF excimer laser scanner model NSR-S610C (Nikon Corp., NA 1.30, σ 0.98/0.78, 35° dipole illumination, 6% halftone phase shift mask), the resist film was exposed to s-polarized illumination through a mask having a line-and-space pattern consisting of 90 nm lines in Y direction at a pitch of 180 nm and in an exposure dose which was more than an optimum dose to provide a 1:1 line-and-space pattern. Immediately after exposure, the resist film was baked at 100° C. for 60 seconds and then developed for 30 seconds with a 2.38 wt % TMAH aqueous solution, obtaining a first pattern consisting of lines of 45 nm size at a pitch of 180 nm.

Each of the pattern protective coating materials of the composition shown in Table 1 was coated on the first pattern and baked at 100° C. for 60 seconds. Development for 30 seconds with a 2.38 wt % TMAH aqueous solution was followed by rinsing with pure water to strip off the extra protective coating material. Subsequent baking at 160° C. for 60 seconds caused intense crosslinking to the resist pattern surface. On the first pattern, the same resist material and the same topcoat material as above were coated and baked under the same conditions as above.

By immersion lithography using an ArF excimer laser scanner model NSR-S610C (Nikon Corp., NA 1.30, σ 0.98/0.78, 35° dipole illumination, 6% halftone phase shift mask), the second resist film was exposed to s-polarized illumination through a mask having a line-and-space pattern consisting of 90 nm lines in Y direction at a pitch of 180 nm, in an exposure dose which was more than an optimum dose to provide a 1:1 line-and-space pattern, and at a position shifted 45 nm in X direction from the first pattern. Immediately after exposure, the second resist film was baked at 100° C. for 60 seconds and then developed for 30 seconds with a 2.38 wt % TMAH aqueous solution, obtaining a second pattern consisting of lines of 45 nm size at a pitch of 180 nm in the space portion of the first pattern.

The size of the first pattern after coating, baking and pure water removal of the protective coating material, and the width of lines in each of the first and second patterns after formation of the second pattern were measured using a measuring SEM model S-9380 (Hitachi Hitechnologies).

The results are shown in Table 6.

TABLE 6

| | | | Size of | | |
|---|---|---|---|---|---|
| | | | 1st pattern | Size of | |
| | | | after removal | 1st pattern after | |
| | Resist | Protective | of pattern | 2nd pattern | Size of 2nd |
| | material | coating material | protective film | formation | pattern |
| Example 38 | Resist 1 | Pattern protective | 46 nm | 51 nm | 45 nm |
| | | film 2 | | | |
| Example 39 | Resist 1 | Pattern protective | 46 nm | 48 nm | 45 nm |
| | | film 3 | | | |
| Example 40 | Resist 1 | Pattern protective | 46 nm | 54 nm | 45 nm |
| | | film 4 | | | |
| Example 41 | Resist 1 | Pattern protective | 46 nm | 48 nm | 45 nm |
| | | film 5 | | | |
| Example 42 | Resist 1 | Pattern protective | 45 nm | 49 nm | 45 nm |
| | | film 6 | | | |
| Example 43 | Resist 1 | Pattern protective | 44 nm | 50 nm | 45 nm |
| | | film 7 | | | |
| Example 44 | Resist 1 | Pattern protective | 44 nm | 49 nm | 45 nm |
| | | film 8 | | | |
| Example 45 | Resist 1 | Pattern protective | 47 nm | 49 nm | 45 nm |
| | | film 9 | | | |
| Example 46 | Resist 1 | Pattern protective | 46 nm | 52 nm | 45 nm |
| | | film 11 | | | |
| Example 47 | Resist 1 | Pattern protective | 46 nm | 52 nm | 46 nm |
| | | film 12 | | | |
| Example 48 | Resist 1 | Pattern protective | 46 nm | 52 nm | 46 nm |
| | | film 13 | | | |
| Example 49 | Resist 1 | Pattern protective | 46 nm | 52 nm | 46 nm |
| | | film 14 | | | |
| Example 50 | Resist 1 | Pattern protective | 46 nm | 54 nm | 45 nm |
| | | film 15 | | | |
| Example 51 | Resist 1 | Pattern protective | 46 nm | 52 nm | 46 nm |
| | | film 16 | | | |
| Example 52 | Resist 1 | Pattern protective | 46 nm | 47 nm | 46 nm |
| | | film 17 | | | |
| Example 53 | Resist 1 | Pattern protective | 46 nm | 47 nm | 46 nm |
| | | film 18 | | | |
| Example 54 | Resist 1 | Pattern protective | 46 nm | 47 nm | 46 nm |
| | | film 19 | | | |
| Example 55 | Resist 1 | Pattern protective | 46 nm | 47 nm | 46 nm |
| | | film 20 | | | |
| Example 56 | Resist 1 | Pattern protective | 49 nm | 51 nm | 46 nm |
| | | film 21 | | | |
| Example 57 | Resist 1 | Pattern protective | 46 nm | 47 nm | 46 nm |
| | | film 22 | | | |
| Example 58 | Resist 1 | Pattern protective | 46 nm | 48 nm | 46 nm |
| | | film 23 | | | |
| Example 59 | Resist 1 | Pattern protective | 49 nm | 52 nm | 51 nm |
| | | film 24 | | | |

### Double Patterning Test II

On a substrate (silicon wafer) having an antireflective coating (ARC-29A, Nissan Chemical Industries, Ltd.) of 80 nm thick, resist material 1 of the composition shown in Table 2 was spin coated, then baked on a hot plate at 100° C. for 60 seconds to form a resist film of 100 nm thick. Topcoat material TC1 of the composition shown in Table 3 was coated thereon and baked at 90° C. for 60 seconds to form a topcoat of 50 nm thick.

By immersion lithography using an ArF excimer laser scanner model NSR-S610C (Nikon Corp., NA 1.30, σ 0.98/0.78, 20° dipole illumination, s-polarized illumination, 6% halftone phase shift mask), the coated substrate was exposed to radiation in a line-and-space pattern consisting of 40 nm lines in X direction. Immediately after exposure, the resist film was baked at 100° C. for 60 seconds and then developed for 30 seconds with a 2.38 wt % TMAH aqueous solution, obtaining a first line-and-space pattern with a size of 40 nm.

Each of the pattern protective coating materials of the composition shown in Table 1 was coated on the first pattern and baked at 100° C. for 60 seconds. Development for 30 seconds with a 2.38 wt % TMAH aqueous solution was followed by rinsing with pure water to strip off the extra protective coating material. Subsequent baking at 160° C. for 60 seconds caused intense crosslinking to the resist pattern surface. On the first pattern, the same resist material and the same topcoat material as above were coated and baked under the same conditions as above.

By immersion lithography using an ArF excimer laser scanner model NSR-S610C (Nikon Corp., NA 1.30, σ 0.98/0.78, 20° dipole illumination, s-polarized illumination, 6% halftone phase shift mask), the second resist film was exposed to radiation in a line-and-space pattern consisting of 40 nm lines in Y direction. Immediately after exposure, the resist film was baked at 100° C. for 60 seconds and then developed for 30 seconds with a 2.38 wt % TMAH aqueous solution, obtaining a second pattern with a size of 40 nm.

The size of the first pattern after coating, baking and pure water removal of the protective coating material, and the width of lines in each of the orthogonally crossing first and second patterns after formation of the second pattern were measured using a measuring SEM model S-9380 (Hitachi Hitechnologies).

The results are shown in Table 7.

TABLE 7

| | | | Size of | | |
|---|---|---|---|---|---|
| | | | 1st pattern | Size of | |
| | | | after removal | 1st pattern after | |
| | Resist | Protective | of pattern | 2nd pattern | Size of 2nd |
| | material | coating material | protective film | formation | pattern |
| Example 60 | Resist 1 | Pattern protective | 41 nm | 50 nm | 41 nm |
| | | film 2 | | | |
| Example 61 | Resist 1 | Pattern protective | 41 nm | 52 nm | 40 nm |
| | | film 3 | | | |
| Example 62 | Resist 1 | Pattern protective | 41 nm | 53 nm | 40 nm |
| | | film 4 | | | |
| Example 63 | Resist 1 | Pattern protective | 41 nm | 49 nm | 41 nm |
| | | film 5 | | | |
| Example 64 | Resist 1 | Pattern protective | 41 nm | 48 nm | 40 nm |
| | | film 6 | | | |
| Example 65 | Resist 1 | Pattern protective | 41 nm | 50 nm | 40 nm |
| | | film 7 | | | |
| Example 66 | Resist 1 | Pattern protective | 41 nm | 52 nm | 40 nm |
| | | film 8 | | | |
| Example 67 | Resist 1 | Pattern protective | 40 nm | 49 nm | 41 nm |
| | | film 9 | | | |
| Example 68 | Resist 1 | Pattern protective | 41 nm | 52 nm | 41 nm |
| | | film 11 | | | |
| Example 69 | Resist 1 | Pattern protective | 43 nm | 52 nm | 41 nm |
| | | film 12 | | | |
| Example 70 | Resist 1 | Pattern protective | 42 nm | 50 nm | 41 nm |
| | | film 13 | | | |
| Example 71 | Resist 1 | Pattern protective | 41 nm | 50 nm | 41 nm |
| | | film 14 | | | |
| Example 72 | Resist 1 | Pattern protective | 41 nm | 48 nm | 41 nm |
| | | film 15 | | | |
| Example 73 | Resist 1 | Pattern protective | 41 nm | 48 nm | 41 nm |
| | | film 16 | | | |
| Example 74 | Resist 1 | Pattern protective | 41 nm | 45 nm | 41 nm |
| | | film 17 | | | |
| Example 75 | Resist 1 | Pattern protective | 41 nm | 46 nm | 41 nm |
| | | film 18 | | | |
| Example 76 | Resist 1 | Pattern protective | 41 nm | 47 nm | 46 nm |
| | | film 19 | | | |
| Example 77 | Resist 1 | Pattern protective | 41 nm | 46 nm | 41 nm |
| | | film 20 | | | |
| Example 78 | Resist 1 | Pattern protective | 48 nm | 52 nm | 46 nm |
| | | film 21 | | | |
| Example 79 | Resist 1 | Pattern protective | 41 nm | 49 nm | 48 nm |
| | | film 22 | | | |
| Example 80 | Resist 1 | Pattern protective | 41 nm | 48 nm | 47 nm |
| | | film 23 | | | |
| Example 81 | Resist 1 | Pattern protective | 48 nm | 48 nm | 47 nm |
| | | film 24 | | | |

### LWR Evaluation

On a substrate (silicon wafer) having an antireflective coating (ARC-29A, Nissan Chemical Industries, Ltd.) of 80 nm thick, resist material 1 of the composition shown in Table 2 was spin coated, then baked on a hot plate at 100° C. for 60 seconds to form a resist film of 100 nm thick. Topcoat material TC1 of the composition shown in Table 3 was coated thereon and baked at 90° C. for 60 seconds to form a topcoat of 50 nm thick.

By immersion lithography using an ArF excimer laser scanner model NSR-S610C (Nikon Corp., NA 1.30, σ 0.98/0.78, 20° dipole illumination, s-polarized illumination, 6% halftone phase shift mask), the coated substrate was exposed to radiation in a line-and-space pattern consisting of 40 nm lines in X direction. Immediately after exposure, the resist film was baked at 100° C. for 60 seconds and then developed for 30 seconds with a 2.38 wt % TMAH aqueous solution, obtaining a line-and-space pattern with a size of 40 nm.

Each of the pattern protective coating materials of the composition shown in Table 1 was coated on the pattern and baked at 100° C. for 60 seconds, followed by rinsing with pure water as above and baking at 160° C. for 60 seconds to cause intense crosslinking to the resist pattern surface. The line width and line width roughness (LWR) were measured using a measuring SEM model S-9380 (Hitachi Hitechnologies). In Comparative Example, the coated substrate was baked at 160° C. for 60 seconds without coating the pattern protective coating material.

The results are shown in Table 8.

TABLE 8

| | Resist | Protective | Line width | LWR |
|---|---|---|---|---|
| | material | coating material | (nm) | (nm) |
| Example | Resist 1 | Pattern protective film 1 | 41.5 | 3.5 |
| Comparative | Resist 1 | — | 40.8 | 5.5 |
| Example | | | | |

Examples 1 to 37 demonstrate that by treating a resist pattern with a silicon-containing material within the scope of the invention, the resist pattern becomes insolubilized in a resist solvent and a developer even after exposure. In Comparative Examples where the pattern protective film was not applied or silane compounds outside the scope of the invention are applied, the resist pattern is dissolved away in a resist solvent.

Examples 38 to 59 demonstrate that the first resist pattern is insolubilized by the inventive process, and the second pattern is formed between first resist features.

Examples 60 to 81 demonstrate that lines of the second pattern orthogonally intersect lines of the first pattern to form a hole pattern.

Examples 38 to 59 and Examples 60 to 81 both demonstrate that the first resist pattern after removal of the pattern protective film shows little or no size variations, but the first resist pattern after formation of the second resist pattern becomes slightly widened.

Example in Table 8 demonstrates that LWR is reduced by applying the pattern protective film. By applying the pattern protective film in accordance with the patterning process of the invention, not only the freezing effect in double patterning, but also the LWR reducing effect are accomplished.

While the invention has been described with reference to a preferred embodiment, it will be understood by those skilled in the art that various changes may be made and equivalents may be substituted for elements thereof without departing from the scope of the invention. Therefore, it is intended that the invention not be limited to the particular embodiment disclosed as the best mode contemplated for carrying out this invention, but that the invention will include all embodiments falling within the scope of the appended claims.

Japanese Patent Application No. 2008-260512 is incorporated herein by reference.

Although some preferred embodiments have been described, many modifications and variations may be made thereto in light of the above teachings. It is therefore to be understood that the invention may be practiced otherwise than as specifically described without departing from the scope of the appended claims.

1. A patterning process comprising the steps of:
applying a first positive resist material onto a substrate, heat treating to form a first resist film, exposing it to high-energy radiation, heat treating the exposed first resist film, then developing it with a developer to form a first resist pattern,
applying a protective coating solution onto the first resist pattern and the substrate, said protective coating solution comprising a silicon compound having at least one amino group and a hydrolysis reactive group, heating the protective coating solution to form a protective coating covering the surface of the first resist pattern,
applying a second positive resist material on the protective coating, heat treating to form a second resist film, exposing it to high-energy radiation, heat treating the exposed second resist film, and then developing it with a developer.

2. A patterning process comprising the steps of:
applying a first positive resist material onto a substrate, heat treating to form a first resist film, exposing it to high-energy radiation, heat treating the exposed first resist film, then developing it with a developer to form a first resist pattern,
applying a protective coating solution onto the first resist pattern and the substrate, said protective coating solution comprising a silicon compound having at least one amino group and a hydrolysis reactive group, heating the protective coating solution to form a protective coating covering the surface of the first resist pattern, stripping an extra portion of the protective coating using an alkaline developer, solvent, water or a mixture thereof,
applying a second positive resist material on the protective coating and the substrate, heat treating to form a second resist film, exposing it to high-energy radiation, heat treating the exposed second resist film, and then developing it with a developer.

3. A patterning process comprising the steps of:
applying a first positive resist material onto a substrate, heat treating to form a first resist film, exposing it to high-energy radiation, heat treating the exposed first resist film, then developing it with a developer to form a first resist pattern,
applying a protective coating solution onto the first resist pattern and the substrate, said protective coating solution comprising a silicon compound having at least one amino group and a hydrolysis reactive group,
applying heat for crosslinking and curing the surface of the first resist pattern adjacent to the protective coating, stripping a non-crosslinked portion of the protective coating using an alkaline developer, solvent, water or a mixture thereof,
applying further heat for insolubilizing the surface of the first resist film,
applying a second positive resist material on the protective coating and the substrate, heat treating to form a second resist film, exposing it to high-energy radiation, heat treating the exposed second resist film, and then developing it with a developer.

4. The patterning process of claim 1 wherein the hydrolysis reactive group is an alkoxy group.

5. The patterning process of claim 1 wherein the silicon compound having at least one amino group and a hydrolysis reactive group is a silane compound having the general formula (1) or (2) or a (partial) hydrolytic condensate thereof, 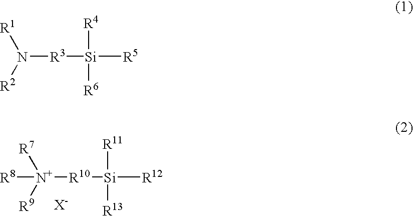
wherein R¹, R², R⁷, R⁸, and R⁹ are each independently hydrogen, a straight, branched or cyclic C₁-C₁₀ alkyl group which may have an amino, ether (—O—), ester (—COO—) or hydroxyl group, or a C₆-C₁₀ aryl, C₂-C₁₂ alkenyl or C₇-C₁₂ aralkyl group which may have an amino group, or R¹ and R², R⁷ and R⁸, R⁸ and R⁹, or R⁷ and R⁹ may bond together to form a ring with the nitrogen atom to which they are attached,
R³ and R¹⁰ are each independently a straight, branched or cyclic C₁-C₁₂ alkylene group which may have an ether (—O—), ester (—COO—), thioether (—S—), phenylene or hydroxyl group,
R⁴ to R⁶ and R¹¹ to R¹³ are each independently hydrogen, a C₁-C₆ alkyl, C₆-C₁₀ aryl, C₂-C₁₂ alkenyl, C₁-C₆ alkoxy, C₆-C₁₀ aryloxy, C₂-C₁₂ alkenyloxy, C₇-C₁₂ aralkyloxy or hydroxyl group, at least one of R⁴ to R⁶ and R¹¹ to R¹³ being alkoxy or hydroxyl, and
X⁻ is an anion.

6. The patterning process of claim 1 wherein the silicon compound having at least one amino group and a hydrolysis reactive group is a silane compound having the general formula (3) or (4) or a (partial) hydrolytic condensate thereof, 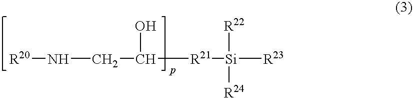
wherein R²⁰ is hydrogen, or a straight, branched or cyclic C₁-C₂₀ alkyl, C₆-C₁₀ aryl or C₂-C₁₂ alkenyl group which may have a hydroxyl, ether, ester or amino group,
p is 1 or 2, when p is 1, R²¹ is a straight, branched or cyclic C₁-C₂₀ alkylene group which may have an ether, ester or phenylene group, when p is 2, R²² is the alkylene group with one hydrogen atom being eliminated,
R²² to R²⁴ are each independently hydrogen, or a C₁-C₆ alkyl, C₆-C₁₀ aryl, C₂-C₁₂ alkenyl, C₁-C₆ alkoxy, C₆-C₁₀ aryloxy, C₂-C₁₂ alkenyloxy, C₇-C₁₂ aralkyloxy or hydroxyl group, at least one of R²² to R²⁴ being alkoxy or hydroxyl, and 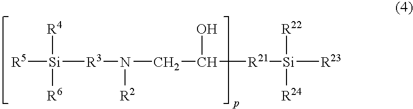
wherein R² is hydrogen, a straight, branched or cyclic C₁-C₁₀ alkyl group which may have an amino, ether (—O—), ester (—COO—) or hydroxyl group, or a C₆-C₁₀ aryl, C₂-C₁₂ alkenyl or C₇-C₁₂ aralkyl group which may have an amino group,
R³ is a straight, branched or cyclic C₁-C₁₂ alkylene group which may have an ether (—O—), ester (—COO—), thioether (—S—), phenylene or hydroxyl group,
R⁴ to R⁶ are each independently hydrogen, a C₁-C₆ alkyl, C₆-C₁₀ aryl, C₂-C₁₂ alkenyl, C₁-C₆ alkoxy, C₆-C₁₀ aryloxy, C₂-C₁₂ alkenyloxy, C₇-C₁₂ aralkyloxy or hydroxyl group, at least one of R⁴ to R⁶ being alkoxy or hydroxyl, and
R²¹ to R²⁴ and p are as defined above.

7. The patterning process of claim 1 wherein the protective coating solution further comprises a silane compound having the general formula (5):
R³¹ₘ₁R³²ₘ₂R³³ₘ₃Si(OR)₍₄₋ₘ₁₋ₘ₂₋ₘ₃₎ (5)
wherein R is C₁-C₃ alkyl, R³¹, R³² and R³³ are each independently hydrogen or C₁-C₃₀ monovalent organic group, m1, m2 and m3 are each equal to 0 or 1, m1+m2+m3 is 0 to 3, and/or a water-soluble resin.

8. The patterning process of claim 1 wherein the protective coating solution further comprises a monohydric alcohol of 3 to 8 carbon atoms and/or water.

9. The patterning process of claim 1 wherein the exposure steps to form the first and second resist patterns are carried out by immersion lithography including using an ArF excimer laser of 193 nm wavelength and holding a liquid having a refractive index of at least 1.4 between a lens and the substrate.

10. The patterning process of claim 9 wherein the liquid having a refractive index of at least 1.4 is water.

11. The patterning process of claim 1 wherein the second pattern is formed in a space portion of the first pattern whereby the distance between pattern features is reduced.

12. The patterning process of claim 1 wherein the second pattern is formed so as to intersect the first pattern.

13. The patterning process of claim 1 wherein in a space portion where features of the first pattern are not formed, the second pattern is formed in a direction different from the first pattern.

14. The patterning process of claim 1, further comprising the step of applying a silicon-containing film as a bottom layer film beneath the resist.

15. The patterning process of claim 1, further comprising the steps of forming a carbon film having a carbon content of at least 75% by weight on a processable substrate, and applying a silicon-containing intermediate film thereon, prior to the formation of the resist film.
